(19) United States
(12) Patent Application Publication
(10) Pub. No.: US 2013/0177848 A1
(43) Pub. Date: Jul. 11, 2013

(54) Polymer, Resist Material Containing Same, and Method for Forming Pattern Using Same

(71) Applicants: Yusuke Kanto, Kawasaki-shi (JP); Shinichi Sumida, Kawagoe-shi (JP); Kazuhiko Maeda, Chiyoda-ku (JP)

(72) Inventors: Yusuke Kanto, Kawasaki-shi (JP); Shinichi Sumida, Kawagoe-shi (JP); Kazuhiko Maeda, Chiyoda-ku (JP)

(73) Assignee: CENTRAL GLASS COMPANY LIMITED, YAMAGUCHI (JP)

(21) Appl. No.: 13/822,842

(22) PCT Filed: Sep. 9, 2011
(86) PCT No.: PCT/JP2011/070746

§ 371 Date: Mar. 13, 2013

(30) Foreign Application Priority Data
Sep. 14, 2010 (JP) 2010-205474
Sep. 7, 2011 (JP) 2011-194890

(51) Int. Cl. G03F 7/039

(52) U.S. Cl. CPC G03F 7/039
USPC 430/270.1; 526/309; 526/245; 430/326

(57) ABSTRACT

A polymer containing a repeating unit represented by the following general formula (1) and a repeating unit having an acid-releasable group.

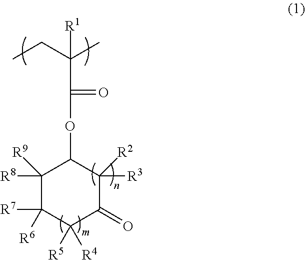

### TECHNICAL FIELD

The present invention relates to: a polymer useful as a chemically amplified resist material suitable for a microfabrication technology, particularly for photolithography in the fabrication process of semiconductor devices and the like; a resist material containing the same; and a pattern-forming method using the resist material.

### BACKGROUND OF THE INVENTION

In recent years, a microprocessor fabrication technique has been remarkably progressing. On highly integrated circuits, transistors of which number exceeds 600 million are formed. Such an explosive advance is achieved by making the minimum line width of electronic circuits finer, and results mostly from the trend toward wavelength reduction of ultraviolet rays used for lithography and from the trend toward a highly sensitive and highly sophisticated resist. Incidentally, lithography is a method for exposing a photosensitive material (or a photoresist, and hereinafter referred to merely as a resist) that has been applied to a substrate surface so as to have a desired pattern. Lithography is a technique of forming a resist pattern on a substrate under the favor of the deference in solubility in a developing solution between exposed and unexposed portions of resist.

At present, lithography using an argon fluoride (hereinafter abbreviated as ArF) excimer laser that oscillates ultraviolet rays at a wavelength of 193 nm is on its way to being introduced seriously. As its light source, the above-mentioned ArF excimer laser is commercialized, but in the future, studies will be developed toward commercialization of Extreme UltraViolet (hereinafter abbreviated as EUV) using an extreme ultraviolet ray having a further shorter wavelength (a wavelength of 13.5 nm).

Additionally, as for a reduction projection lens used in a stepper-type exposure apparatus serving as a semiconductor device fabrication apparatus, the resolution performance is dramatically enhanced by the refinement in optical designs for the lens, which contributes to the production of high-density highly integrated semiconductor devices in the photolithography technique. The stepper-type exposure apparatus is an apparatus that reduces the pattern of reticle (a kind of high-performance photomasks) through the reduction projection lens and exposes a resist applied onto a wafer. The optical resolution of the lens used in the stepper-type exposure apparatus is represented by NA (Numerical Aperture), and its value of around 0.9 is defined as a physical limit in air but it has already been attained at the present time.

For example, concerning lithography using the ArF excimer laser, it is now on attempt to raise NA to 1.0 or more by filling a space defined between a lens and a wafer with a medium having a larger refractive index than air. In particular, an exposure technique adopting an immersion method using pure water (hereinafter, pure water may simply be referred to as water) as the medium, i.e., an immersion lithography is receiving attention.

Additionally, in lithography using the ArF excimer laser, in addition to immersion lithography, there have been studied double patterning (double exposure) method adopted as a lithography technique which attains a finer patterning by conducting exposure two times on one circuit, and a method combining immersion lithography and double patterning.

As a resist material suitable for such lithography techniques (lithography using ultraviolet rays radiated from the ArF excimer laser, immersion lithography, double patterning, EUV lithography using extreme ultraviolet rays and the like), chemically amplified resist materials are employed. Of these, a resist material having good adhesiveness to a substrate (such as a wafer) is necessary for formation of a fine and accurate pattern, so that the manufacturers eagerly pursue the research and development of a novel adhesive monomer.

Though it is said that the adhesiveness results from polar functional groups, lactone is the only one currently used as a polar group. A representative monomer thereof is methacryloyloxy butyrolactone, methacryloyloxy valerolactone, 5-methacryloyloxy-2,6-norbornanecarbolactone or the like. For example, there is disclosed in Patent Publication 1 5-methacryloyloxy-2,6-norbornanecarbolactone as a photoresist composition. Monomers having a polar functional group, other than lactone, can also be expected to have a sufficient adhesiveness, but very few of these are used for resist.

In Patent Publication 2, a high polymer compound that contains a group represented by the following formula, and a chemically amplified positive type resist material containing an organic solvent and an acid generator are disclosed. This resist material is sensitive to high energy beams and particularly excellent in sensitivity at wavelengths of 170 nm or less. Furthermore, it seems to improve transparency of a resist and excellent in plasma etching resistance.

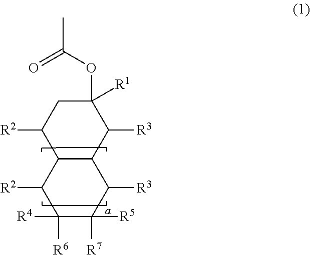

(R¹ to R³ are H, F or an alkyl group or a fluorinated alkyl group; R⁴ and R⁵ are H or F; R⁶ and R⁷ are H, F or an alkyl group or a fluorinated alkyl group; at least one of R⁶ and R⁷ contains one or more F; a is 0 or 1.)

In Patent Publication 3, there is disclosed a positive type resist composition provided by using 2-hydroxy-3-pinanone acrylate or methacrylate represented by the following formula and a polymer or copolymer thereof. The composition seems to have high transparency to ArF excimer laser beams and excellent in sensitivity, resist pattern shape, dry etching resistance and adhesiveness.

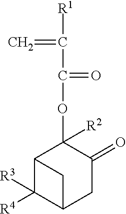

(R¹ represents hydrogen atom or methyl group; R², R³ and R⁴ represent each hydrogen atom or a lower alkyl group.)

In Patent Publication 4, a monomer having a naphthalene ring represented by the following formula and a polymer compound including a repeating unit derived from the monomer are disclosed. With this, it seems that high-grade microfabrication is made possible by a double-patterning process or the like by providing a pattern-freezable resist material and a pattern-forming method including a step of curing a resist film.

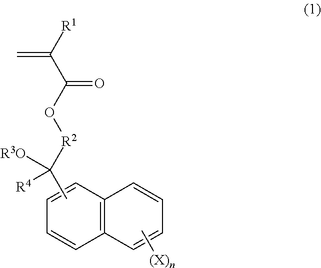

(R¹ is H, F, a methyl group or a trifluoromethyl group; R² is a C₁-C₁₀ bivalent organic group; R³ and R⁴ are each H or a C₁-C₁₀ monovalent organic group; R² and R³ or R² and R⁴ may be linked to each other to form a cyclic structure together with a carbon atom to which they are bonded; R³ and R⁴ may be linked to each other to form a cyclic structure together with a carbon atom to which they are bonded; X is a hydroxy group, a halogen atom or a C₁-C₁₀ monovalent organic group; and n is 0-7.)

In Patent Publication 5, disclosed is a radiation-sensitive resin composition obtained by using a compound for a radiation-sensitive resin composition, the compound being represented by the following formula. This composition seems to be useful as a chemically amplified resist sensitive to active beams, e.g., deep ultraviolet rays represented by a KrF excimer laser (a wavelength of 248 nm) or the ArF excimer laser, and seems to be enormously suitably usable for integrated circuit devices expected to be proceeding toward microfabrication.

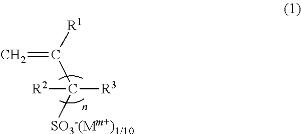

(R¹ represents a methyl group, a trifluoromethyl group or a hydrogen atom; R² and R³ mutually independently represent a hydrogen atom, a substituted or unsubstituted C₁-C₁₀ straight chain or branched alkyl group; M^{m+} represents an onium cation; m represents a natural number of 1-3; and n represents a natural number of 0-3.)

### REFERENCES ABOUT PRIOR ART

### Patent Publication

Patent Publication 1: Japanese Patent Application Publication No. 2000-26446
Patent Publication 2: Japanese Patent Application Publication No. 2002-327013
Patent Publication 3: Japanese Patent Application Publication No. 2004-339521
Patent Publication 4: Japanese Patent Application Publication No. 2010-53163
Patent Publication 5: International Application Publication No. 2006/121096 Pamphlet

### SUMMARY OF THE INVENTION

### Problems to be Solved by the Invention

An object of the present invention is to provide a novel polymer having a great adhesiveness to a substrate such as a wafer and the like and used for a resist resin that allows formation of a fine pattern in photolithography. Particularly, a further object of the present invention is to provide: a novel polymer having a great adhesiveness to a substrate such as a wafer and the like and useful as a chemically amplified resist material suitable for a micropatterning process in lithography where exposure is conducted with ultraviolet light having a wavelength of 300 nm or less (such as a lithography that employs KrF excimer laser or ArF excimer laser as the light source of an exposure apparatus, immersion lithography that employs ArF excimer laser, double patterning that uses ArF excimer laser and EUV lithography); a resist material containing the same; and a pattern-forming method using the resist material.

Furthermore, a further object of the present invention is to provide: an adhesive novel polymer useful as a chemically amplified resist material that can be applied also in double patterning, the polymer exhibiting a moderate water repellency and a solubility in alcohol-based solvent before exposure while exhibiting a rapid solubility in a developing solution after exposure, the polymer having a great depth of focus not only in dry exposure but also in immersion exposure thereby facilitating the control of focusing, the polymer resulting in few mask error factors (a dimensional difference between a pattern of mask and a pattern transferred to a substrate) and line-edge roughness (a phenomenon where an edge of resist deviates from a straight line projectingly or depressingly) thereby allowing the formation of high-resolution pattern, the polymer being able to become a solution by using a solvent insoluble in conventional resist materials such as C₅-C₂₀ alcohol-based solvents and the like; a resist material containing the same; and a pattern-forming method using the resist material.

### Means for Solving the Problems

In view of the above, the present inventors eagerly made studies on the above problems.

If carbonyl group is contained as a repeating unit in a polymer used for a resist material or if a repeating unit that constitutes a polymer is provided to contain a ketone structure, the polymer exhibits a great adhesiveness to a substrate such as wafer and the like at the time of being provided as a resist or a film, by virtue of the polarity of the carbonyl group. This is similar to a hitherto used lactone. In addition, when such a polymer is used as a resist, the water repellency and the hydrophilicity are brought into balance against water and the solubility in an alcohol-based solvent becomes sufficiently exhibited. As a result, it was found that a great resist pattern can be formed. By considering the fact that a substituent can easily be introduced into the structure of polymer at both α-positions of carbonyl group as necessary, it became evident that a polymer which contains a repeating unit having a ketone structure is more useful as a resist material than a polymer which contains a repeating unit having a lactone structure.

More specifically, the present invention relates to: a polymer that contains a repeating unit having a carbonyl group to obtain adhesiveness, and a repeating unit having an acid-releasable group (to be decomposed by irradiation of high-energy ray such as ultraviolet rays and the like so as to donate acid) to obtain a development performance as a resist material in lithography; a resist material containing the same; and a pattern-forming method using the resist material.

The present invention can be known from the following Inventions 1 to 10.

[Invention 1]

A polymer characterized by containing a repeating unit represented by the following general formula (1) and a repeating unit having an acid-releasable group.

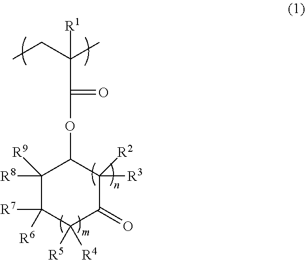

(In the formula (1), R¹ mutually independently represents a hydrogen atom, a halogen atom, a methyl group, or a trifluoromethyl group. R² to R⁹ mutually independently represent a hydrogen atom, a C₁-C₂₀ linear or C₃-C₂₀ branched or cyclic hydrocarbon group, wherein some of the carbon atoms constituting the hydrocarbon groups may be replaced with oxygen atom(s), two hydrogen atoms binding to the same carbon may be replaced with an oxygen atom to form ═O, H of a C—H bond of the hydrocarbon may be replaced with OH to form C—OH, and some or all of the hydrogen atoms constituting R² to R⁹ may be replaced with fluorine atom(s). Additionally, some or all of R² to R⁹ may be combined to form a cyclic structure, and “n” and “m” represent the number of carbon atoms and mutually independently represent an integer of 0 to 5.)

[Invention 2]

A polymer of Invention 1 or Invention 2, characterized by further containing a repeating unit having 1,1,1,3,3,3-hexafluoro-2-hydroxyisopropyl [—C(CF₃)₂OH] group (this group may hereinafter be referred to as an HFIP group) or a repeating unit having an adhesive group.

A polymer that only contains a repeating unit having carbonyl group for obtaining adhesiveness is disclosed by Patent Publications 1 to 4. A polymer that contains a repeating unit having a salt is disclosed by Patent Publication 5. However, a polymer that contains both the repeating unit having carbonyl group for obtaining adhesiveness and the repeating unit having a salt as the following polymer has not been known.

Furthermore, in the polymer of the present invention, a repeating unit having a salt and contained together with the repeating unit represented by the general formula (1) is exemplified by the following general formula (2) or (3).

[Invention 3]

A polymer of Invention 1 or 2, characterized by further containing a repeating unit having a salt represented by the following formula (2) or the following general formula (3).

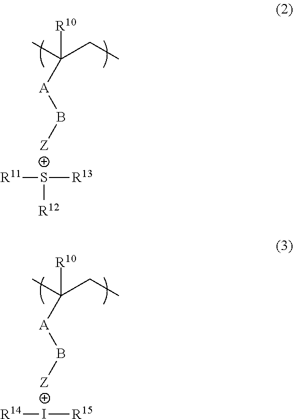

(In the formulas (2) and (3), R¹⁰ mutually independently represents a hydrogen atom, a halogen atom, a methyl group, or a trifluoromethyl group. “A” mutually independently represents a single bond, a methylene group, a phenylene group, —O—, —(C═O)—O— or —(C═O)—NR¹⁶—, wherein R¹⁶ in —(C═O)—NR¹⁶— mutually independently represents a hydrogen atom, a C₁-C₂₀ linear or C₃-C₂₀ branched or cyclic hydrocarbon group, some or all of the hydrogen atoms may be replaced with fluorine atom(s), hydroxyl group(s) or alkoxyl group(s), and the hydrocarbon group may have at least one kind selected from —O—, —(C═O)—O—, —(C═O)—NH—, —(C═O)—, —O—(C═O)—NH— and —NH—(C═O)—NH—. “B” mutually independently represents a single bond, a C₁-C₂₀ linear or C₃-C₂₀ branched or cyclic alkylene or phenylene group, wherein some or all of the hydrogen atoms may be replaced with fluorine atom(s), hydroxyl group(s) or alkoxyl group(s), and the hydrocarbon group may have at least one kind selected from —O—, —(C═O)—O—, —(C═O)—NH—, —(C═O)—, —O—(C═O)—NH— and —NH—(C═O)—NH—. “Z” mutually independently represents SO₃⁻, CO₂⁻, (CF₃SO₂)₂C⁻, or CF₃SO₂N⁻. R¹¹ to R¹³ mutually independently represent a C₁-C₃₀ linear or branched alkyl group that may have a substituent, a C₃-C₃₀ cyclic monovalent hydrocarbon group that may have a substituent, a C₆-C₃₀ aryl group that may have a substituent, or a monovalent heterocyclic organic group that may have a substituent and has the number of atoms of 4 to 30, wherein any two or more of R¹¹ to R¹³ may be bonded to each other through a sulfur atom to form a cyclic structure. R¹⁴ and R¹⁵ mutually independently represent a C₁-C₃₀ linear or C₃-C₃₀ branched alkyl group that may have a substituent, a C₃-C₃₀ cyclic monovalent hydrocarbon group that may have a substituent, a C₆-C₃₀ aryl group that may have a substituent, or a monovalent heterocyclic organic group that may have a substituent and has the number of atoms of 4 to 30. Alternatively, R¹⁴ and R¹⁵ may be bonded to each other through an iodine atom to form a cyclic structure.)

In the present invention, the number of atoms means the number of atoms having a valence of two or more. Such atoms are exemplified by carbon, oxygen, sulfur, phosphorus, selenium and the like.

[Invention 4]

A resist material characterized by containing a polymer as discussed in any one of Inventions 1 to 3.

[Invention 5]

A resist material of Invention 4, characterized by further containing at least one kind of an acid generator, a basic compound and an organic solvent.

[Invention 6]

A resist material of Invention 5, characterized in that a C₅-C₂₀ alcohol-based solvent is used as the organic solvent.

[Invention 7]

A pattern-forming method characterized by containing: a first step of applying a resist material as discussed in any one of Inventions 4 to 6 to a substrate; a second step of subjecting the substrate to heat treatment to form a resist film and then exposing the resist film to an ultraviolet light or extreme ultraviolet light having a wavelength of 300 nm or less through a photomask by using an exposure apparatus; and a third step of carrying out development by dissolving an exposed portion of the resist film in a developing solution thereby forming a pattern in the substrate.

[Invention 8]

A pattern-forming method of Invention 7, characterized by adopting immersion lithography where water is inserted between a wafer and a projection lens and an ultraviolet light is radiated from an ArF excimer laser of a wavelength of 193 nm in use of an exposure apparatus.

[Invention 9]

A pattern-forming method according to double patterning where a first resist pattern is formed on a substrate and then a second resist pattern is formed on the first resist pattern, characterized in that a resist material as discussed in any one of Inventions 4 to 6 is used.

[Invention 10]

A pattern-forming method according to EUV lithography that uses an ultraviolet light having a wavelength of 13.5 nm, characterized in that a resist material as discussed in any one of Inventions 4 to 6 is used.

### Effects of the Invention

The resist material obtained by using the polymer of the present invention not only exhibits an excellent adhesiveness to a substrate such as a wafer and the like when applied to the substrate as a resist but also provides well-balanced water repellency and hydrophilicity against water as a resist material, exhibits a sufficient solubility in an alcohol-based solvent, has a great depth of focus not only in dry exposure but also in immersion exposure thereby facilitating the control of focusing and results in few mask error factors and line-edge roughness, thereby allowing the formation of high-resolution pattern. Additionally, the resist material is useful as a chemically amplified resist material which can become a solution by using a solvent that does not dissolve conventional resist materials, such as C₅-C₂₀ alcohol-based solvents and the like. Hence this resist material is also useful as a resist material for use in immersion lithography and double patterning process in particular.

Furthermore, the resist material according to the present invention can be used as a resist material suitable for

### MODE(S) FOR CARRYING OUT THE INVENTION

The present invention will hereinafter be discussed in detail.

Repeating units contained in a polymer of the present invention will be discussed in order.

### 1. Repeating Unit Represented by the General Formula (1)

[Invention 1] is a polymer characterized by containing a repeating unit represented by the general formula (1) and a repeating unit having an acid-releasable group.

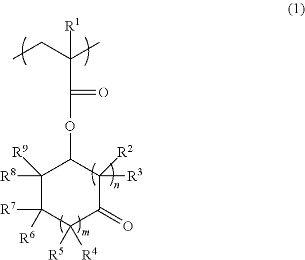

(In the formula (1), R¹ mutually independently represents a hydrogen atom, a halogen atom, a methyl group, or a trifluoromethyl group. R² to R⁹ mutually independently represent a hydrogen atom, a C₁-C₂₀ linear or C₃-C₂₀ branched or cyclic hydrocarbon group, wherein some of the carbon atoms constituting the hydrocarbon groups may be replaced with oxygen atom(s), two hydrogen atoms binding to the same carbon may be replaced with an oxygen atom to form ═O, H of a C—H bond of the hydrocarbon may be replaced with OH to form C—OH, and some or all of the hydrogen atoms constituting R² to R⁹ may be replaced with fluorine atom(s). Additionally, some or all of R² to R⁹ may be combined to form a cyclic structure, and “n” and “m” represent the number of carbon atoms and mutually independently represent an integer of 0 to 5.)

In the repeating unit represented by the general formula (1), the ring should be a 4 to 14-membered ring since “n” and “m” mutually independently represent an integer ranging from 0 to 5. In view of availability of the raw material, however, a 5-membered or 6-membered ring is preferable. In the repeating unit represented by the general formula (1), introduction of an oxygen atom or carbonyl group is useful for adjusting solubility in a solvent, and additionally substitution with fluorine atom (among halogen atoms) is useful for adjusting water repellency and transparency. Hence these are introduced optionally as necessary.

In the repeating unit represented by the general formula (1), examples of R² to R⁹ include C₁-C₂₀ linear or C₃-C₂₀ branched or cyclic hydrocarbon groups such as methyl group, ethyl group, propyl group, isopropyl group, cyclopropyl group, n-propyl group, isopropyl group, sec-butyl group, tert-butyl group, n-pentyl group, cyclopentyl group, sec-pentyl group, neopentyl group, hexyl group, cyclohexyl group, ethylhexyl group, norbornyl group, adamantyl group, vinyl group, allyl group, butenyl group, pentenyl group, ethynyl group, phenyl group, benzyl group, 4-methoxybenzyl group and the like. Some or all of the hydrogen atoms of the above-mentioned functional groups may be replaced with fluorine atom(s).

In addition, R² to R⁹ containing oxygen atom are exemplified by: chain ethers such as methoxy group, ethoxy group, n-propxy group, iso-propxy group, sec-butoxy group, tert-butoxy group, n-pentyloxy group, cyclopentyloxy group, sec-pentyloxy group, neopentyloxy group, hexyloxy group, cyclohexyloxy group, ethylhexyloxy group, norbornyloxy group, adamantyloxy group, allyloxy group, butenyloxy group, pentenyloxy group, ethynyloxy group, phenyloxy group, benzyloxy group, 4-methoxybenzyloxy group, methoxymethyl group, methoxyethoxymethyl group, ethoxyethyl group, butoxyethyl group, cyclohexyloxyethyl group, benzyloxyethyl group, phenethyloxyethyl group, ethoxypropyl group, benzyloxypropyl group, phenethyloxypropyl group, ethoxybutyl group, ethoxyisobutyl group and the like; and cyclic ethers such as tetrahydrofuranyl group, tetrahydropyranyl group and the like.

Acyl group in R² to R⁹ can be exemplified by acetyl group, propionyl group, butyryl group, heptanoyl group, hexanoyl group, valeryl group, pivaloyl group, isovaleryl group, lauryloyl group, myristoyl group, palmitoyl group, stearoyl group, oxalyl group, malonyl group, succinyl group, glutaryl group, adipoyl group, piperoyl group, suberoyl group, azelaoyl group, sebacoyl group, acryloyl group, propioloyl group, methacryloyl group, crotonoyl group, oleoyl group, maleoyl group, fumaroyl group, mesaconoyl group, campholoyl group, benzoyl group, phthaloyl group, isophthaloyl group, terephthaloyl group, naphthoyl group, toluoyl group, hydroatropoyl group, atropoyl group, cinnamoyl group, furoyl group, thenoyl group, nicotinoyl group, isonicotinoyl group and the like.

In R² to R⁸, a functional group having carbonyl group (═C═O) means a functional group obtained in a manner that a carbonyl group is introduced into a linear, branched or cyclic hydrocarbon group. Examples of the functional group include acetyl group, oxoethyl group, oxopropyl group and the like; however, the functional group is not limited to these examples. Additionally, it is also possible to use a functional group in which some or all of the hydrogen atoms of the above-mentioned substituent are replaced with fluorine atom(s).

As a polymerizable monomer that provides a repeating unit constituting the polymer of the present invention, it is preferable to use 4-oxo-CHMA, 3-oxo-CHMA and the like as employed in Examples.

Incidentally, a repeating unit as shown below is identical to the repeating unit represented by the general formula (1) in containing R¹ to R⁹, but different in containing Rx. Contrary to the repeating unit represented by the general formula (1) and having no acid-lability in itself, this repeating unit contains R^{X} and exhibits acid-lability when a carbon bonded to R^{X} is a tertiary carbon atom, so as to provide another function as a resist material.

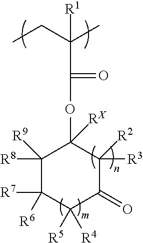

(R^{X} represents a C₁-C₂₀ linear or C₃-C₂₀ branched or cyclic hydrocarbon group, wherein some of the carbon atoms constituting the hydrocarbon group may be replaced with oxygen atom(s), two hydrogen atoms binding to the same carbon may be replaced with an oxygen atom to form ═O, H of a C—H bond of the hydrocarbon may be replaced with OH to form C—OH, and some or all of the hydrogen atoms may be replaced with fluorine atom(s).)

### 2. Repeating Unit Having an Acid-Releasable Group

In a case of preparing a chemically amplified positive type resist material, a polymer which is insoluble or hard to dissolve in a developing solution (usually, an alkali developing solution) and becomes soluble in the developing solution by acid is used as a polymer for a resist. Therefore, in a resist material according to the present invention, it is essential that the polymer of the present invention contains a repeating unit having an acid-releasable group cleavable by acid.

The repeating unit having an acid-releasable group and contained in the polymer of Invention 1 together with the repeating unit represented by the general formula (1) (the acid-releasable group is decomposed by irradiation of high-energy ray such as ultraviolet rays so as to donate acid) is exemplified by repeating unit obtained by replacing a hydrogen atom of carboxyl group of polyacrylic acid, polymethacrylic acid or polytrifluoromethacrylic acid with an acid-releasable group, the examples being classified broadly into tertiary alkyl groups and other functional groups.

Examples of tertiary alkyl groups are tert-butyl group, tert-amyl group, 1,1-diethylpropyl group, 1-methylcyclopentyl group, 1-ethylcyclopentyl group, 1-isopropylcyclopentyl group, 1-propylcyclopentyl group, 1-butylcyclopentyl group, 1-methylcyclohexyl group, 1-ethylcyclohexyl group, 1-isopropylcyclohexyl group, 1-propylcyclohexyl group, 1-butylcyclohexyl group, methyladamantyl group, ethyladamantyl group, isopropyladamantyl group, propyladamantyl group and the like.

Examples of other functional groups are tert-butoxycarbonyl group, tert-amyloxycarbonyl group, 1,1-diethylpropyloxycarbonyl group, 1-ethylcyclopentyloxycarbonyl group, 1-ethyl-2-cyclopentenyloxycarbonyl group, 1-ethoxyethoxycarbonylmethyl group, methoxymethyl group, tert-butylthiomethyl group, phenyldimethylmethoxymethyl group, benzyloxymethyl group, p-methoxybenzyloxymethyl group, 4-methoxyphenoxymethyl group, guaiacolmethyl group, tert-butyloxy group, silyloxymethyl group, 2-methoxyethoxymethyl group, 2-(trimethylsilypethoxymethyl group, tetrahydropyranyl group, tetrahydrothiopyranyl group, 1-methoxycyclohexyl group, 4-methoxytetrahydropyranyl group, 4-methoxytetrahydrothiopyranyl group, 1,4-dioxan-2-yl group, tetrahydrofuranyl group, tetrahydrothiofuranyl group, 1-ethoxyethyl group, 1-methyl-1-methoxyethyl group, 1-methyl-1-benzyloxyethyl group and the like.

In addition, functional groups obtained by replacing some or all of hydrogen atoms of the above-mentioned substituent with fluorine atom(s) are also usable.

### 3. Repeating Unit Having an HFIP Group

When it is required to let the polymer of the present invention have alkali-developable characteristics and hydrophilic characteristics, a repeating unit having an HFIP group may be introduced as the polymer of Invention 2. A polymerizable monomer that can form a repeating unit is correctly exemplified by a group of compounds as shown below.

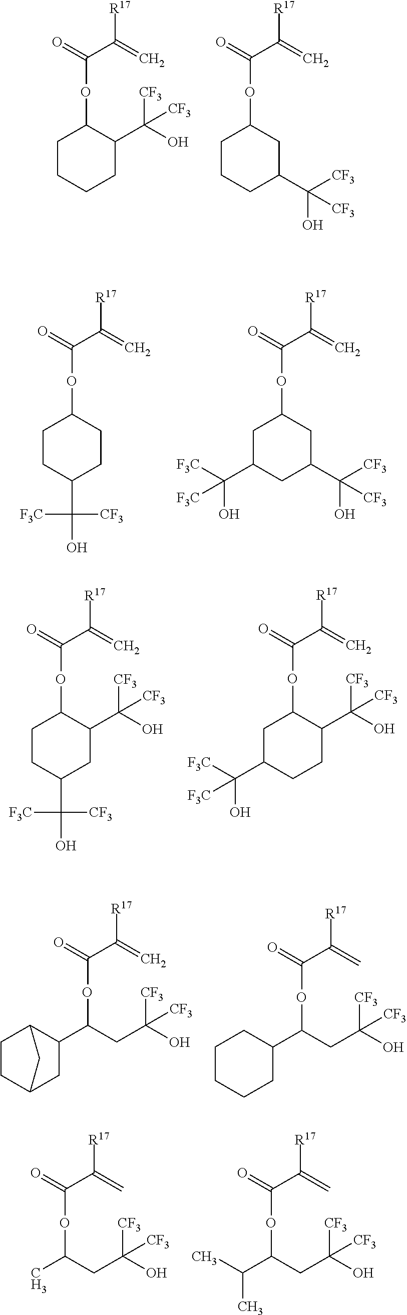

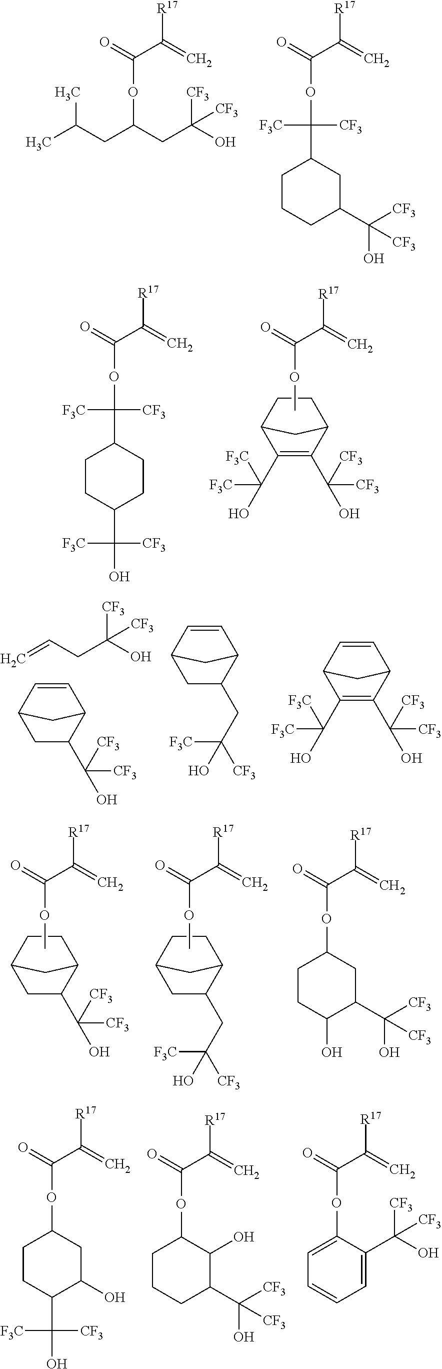

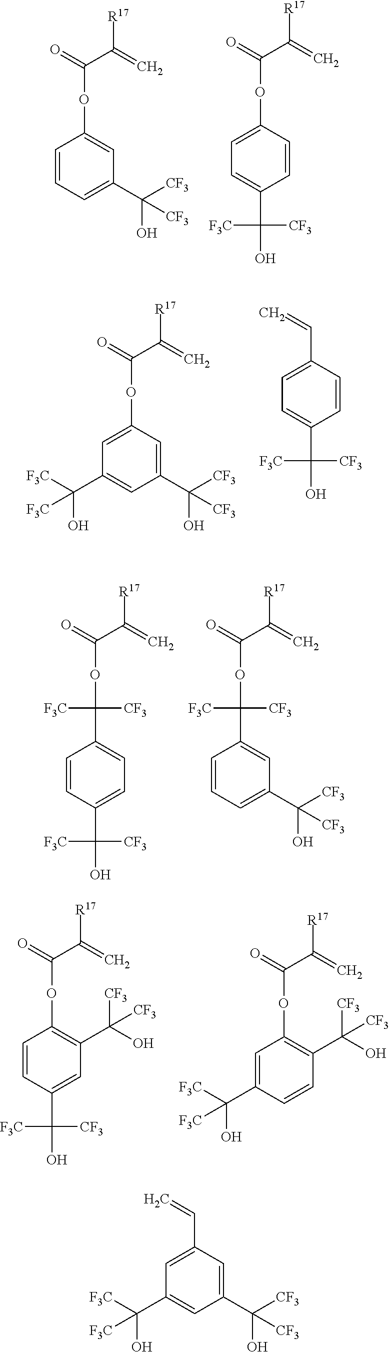

In these formulas, R¹⁷ represents a hydrogen atom, a halogen atom, a methyl group, or a trifluoromethyl group. Additionally, some or all of the hydroxyl groups in hexafluoroisopropyl group may be protected with protective group(s)

### 4. Repeating Unit Having an Adhesive Group

When adhesiveness of the polymer of Invention 1 to a substrate is no enough, a repeating unit having a lactone structure may be introduced as a repeating unit having an adhesive group as the polymer of Invention 2. A polymerizable monomer that can form such a repeating unit can correctly be exemplified by methacryloyloxy butyrolactone, methacryloyloxy valerolactone, 5-methacryloyloxy-2,6-norbornanecarbolactone and the like.

### 5. Repeating Unit Having a Salt

As mentioned as the polymer of Invention 3, the polymer of the present invention may further contain “a repeating unit including a repeating structure unit having an onium salt represented by the general formula (2) or (3)” as a repeating unit having a salt. An onium salt moiety functions as an acid generator and has an action generating sulfonic acid by exposure or heating, and in particular, usable as a radiation-sensitive acid generator contained in a radiation-sensitive resin composition as will be discussed later.

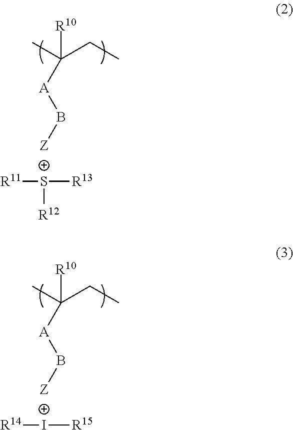

(In the formulas (2) and (3), R¹³ mutually independently represents a hydrogen atom, a halogen atom, a methyl group, or a trifluoromethyl group. “A” mutually independently represents a single bond, a methylene group, a phenylene group, —O—, —(C═O)—O— or —(C═O)—NR¹⁶—, wherein R¹⁶ mutually independently represents a hydrogen atom, a C₁-C₂₀ linear or C₃-C₂₀ branched or cyclic hydrocarbon group, some or all of the hydrogen atoms may be replaced with fluorine atom(s), hydroxyl group(s) or alkoxyl group(s), and the hydrocarbon group may have at least one kind selected from —O—, —(C═O)—O—, —(C═O)—NH—, —(C═O)—, —O—(C═O)—NH— and —NH—(C═O)—NH—. “B” mutually independently represents a single bond, a C₁-C₂₀ linear or C₃-C₂₀ branched or cyclic alkylene or phenylene group, wherein some or all of the hydrogen atoms may be replaced with fluorine atom(s), hydroxyl group(s) or alkoxyl group(s), and the hydrocarbon group may have at least one kind selected from —O—, —(C═O)—O—, —(C═O)—NH—, —(C═O)—, —O—(C═O)—NH— and —NH—(C═O)—NH—. “Z” mutually independently represents SO₃⁻, CO₂⁻, (CF₃SO₂)₂C⁻, or CF₃SO₂N⁻. R¹¹ to R¹³ mutually independently represent a C₁-C₃₀ linear or C₃-C₃₀ branched alkyl group that may have a substituent, a C₃-C₃₀ cyclic monovalent hydrocarbon group that may have a substituent, a C₆-C₃₀ aryl group that may have a substituent, or a monovalent heterocyclic organic group that may have a substituent and has the number of atoms of 4 to 30, wherein any two or more of R¹¹ to R¹³ may be bonded to each other through a sulfur atom to form a cyclic structure. R¹⁴ and R¹⁵ mutually independently represent a C₁-C₃₀ linear or branched alkyl group that may have a substituent, a C₃-C₃₀ cyclic monovalent hydrocarbon group that may have a substituent, a C₆-C₃₀ aryl group that may have a substituent, or a monovalent heterocyclic organic group that may have a substituent and has the number of atoms of 4 to 30. Alternatively, R¹⁴ and R¹⁵ may be bonded to each other through an iodine atom to form a cyclic structure.)

As anion contained in the general formulas (2) and (3), it is possible to cite the following concrete examples.

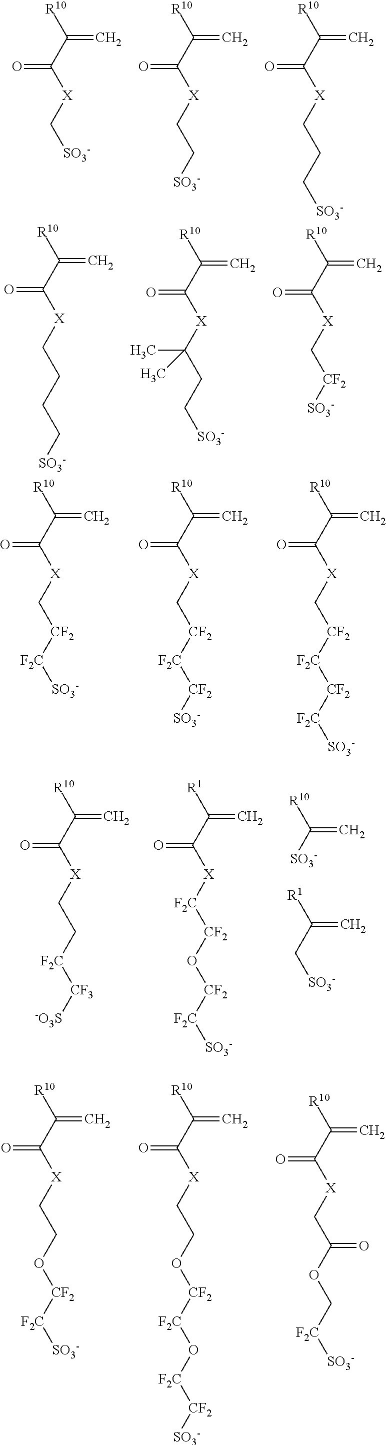

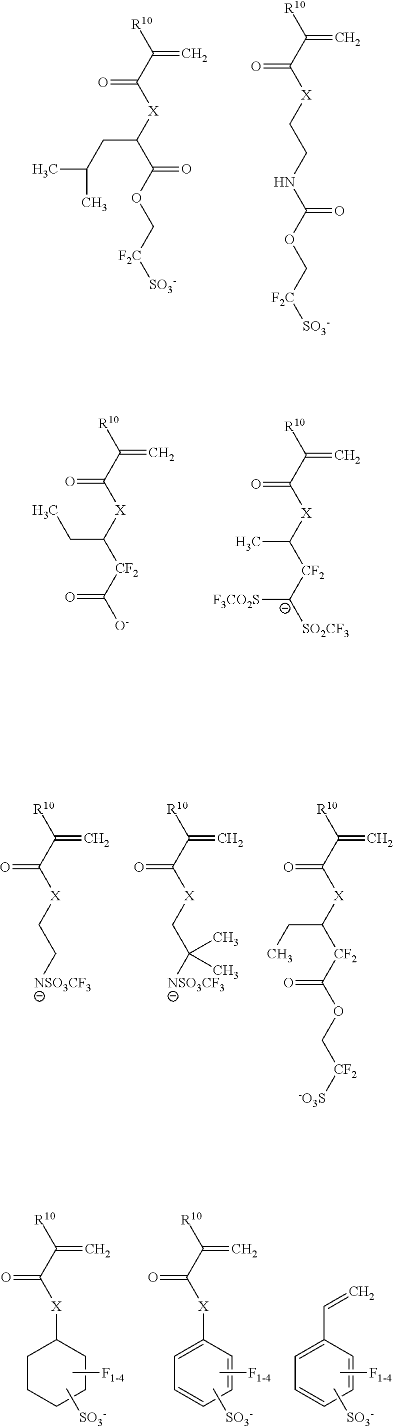

R¹⁰ represents a hydrogen atom, a methyl group or a trifluoromethyl group. “X” represents an oxygen atom or NR¹⁶. R¹⁶ represents a hydrogen atom or a C₁-C₂₀ linear or C₃-C₂₀ branched or cyclic hydrocarbon group, wherein some or all of the hydrogen atoms may be replaced with fluorine atom(s), hydroxyl group(s) or alkoxyl group(s), and the hydrocarbon group may have at least one kind selected from —O—, —(C═O)—O—, —(C═O)—NH—, —(C═O)—, —O—(C═O)—NH— and —NH—(C═O)—NH—.

An onium salt of the present invention limits the structure of the acid to be generated or limits the side of anion, but it does not particularly limit the side of cation.

In the general formula (2) or (3), unsubstituted C₁-C₃₀ linear or C₃-C₃₀ branched monovalent hydrocarbon groups or unsubstituted C₃-C₃₀ cyclic monovalent hydrocarbon groups of R¹¹ to R¹⁵ can be exemplified by alkyl groups such as methyl group, ethyl group, n-propyl group, i-propyl group, n-butyl group, 1-methylpropyl group, 2-methylpropyl group, t-butyl group, n-pentyl group, i-pentyl group, 1,1-dimethylpropyl group, 1-methylbutyl group, 1,1-dimethylbutyl group, n-hexyl group, n-heptyl group, i-hexyl group, n-octyl group, i-octyl group, 2-ethylhexyl group, n-nonyl group, n-decyl group, n-undecyl group, n-dodecyl group, cyclopropyl group, cyclopentyl group, cyclohexyl group, 4-t-butylcyclohexyl group and the like, cyclohexenyl group, a group having norbornene skeleton, a group having norbornane skeleton, a group having isobornyl skeleton, a group having tricyclodecane skeleton, a group having tetracyclododecane skeleton, a group having adamantane skeleton and the like.

As a substituent of the above hydrocarbon group, it is possible to mention, for example, a C₆-C₃₀ aryl group, a C₂-C₃₀ linear or C₃-C₃₀ branched or cyclic alkenyl group, and a group having the number of atoms of 1-30 and contains a hetero atom such as halogen atom, oxygen atom, nitrogen atom, sulfur atom, phosphorus atom, silicon atom and the like. These substituents can also further have arbitrary substituents, for example, at least one kind of the above-mentioned substituents.

As a C₁-C₃₀ linear or C₃-C₃₀ branched or cyclic monovalent hydrocarbon group replaced with the above substituent, it is possible to cite, for example, benzyl group, methoxymethyl group, methylthiomethyl group, ethoxymethyl group, ethylthiomethyl group, phenoxymethyl group, methoxycarbonylmethyl group, ethoxycarbonylmethyl group, acetylmethyl group, fluoromethyl group, trifluoromethyl group, chloromethyl group, trichloromethyl group, 2-fluoropropyl group, (trifluoroacetyl)methyl group, (trichloroacetyl)methyl group, (pentafluorobenzoyl)methyl group, aminomethyl group, (cyclohexylamino)methyl group, (diphenylphosphino)methyl group, (trimethylsilyl)methyl group, 2-phenylethyl group, 3-phenylpropyl group, and 2-aminoethyl group.

Furthermore, as the unsubstituted C₆-C₃₀ aryl group of R₁₁ to R₁₅, it is possible to mention, for example, phenyl group, 1-naphthyl group, 2-naphthyl group, 1-anthryl group and 1-phenanthryl group.

Furthermore, the unsubstituted monovalent heterocyclic organic group having the number of atoms of 4 to 30, represented by R₁₁ to R₁₅, it is possible to mention, for example, furyl group, thienyl group, pyranyl group, pyrrolyl group, thianthrenyl group, pyrazolyl group, isothiazolyl group, isoxazolyl group, pyrazinyl group, pyrimidinyl group, pyridazinyl group, tetrahydropyranyl group, tetrahydrofuranyl group, tetrahydrothiopyranyl group, tetrahydrothiofuranyl group and 3-tetrahydrothiophene-1,1-dioxide group.

As a substituent of the above aryl group or of the monovalent heterocyclic organic group, it is possible to mention a C₁-C₃₀ linear, branched or cyclic alkyl group, a group having the number of atoms of 1-30 and containing a hetero atom such as halogen atom, oxygen atom, nitrogen atom, sulfur atom, phosphorus atom, silicon atom and the like, etc. These substituents can also further have arbitrary substituents, for example, at least one kind of the above substituents.

As the C₆-C₃₀ aryl group replaced with the above substituent, it is possible to mention, for example, o-tolyl group, m-tolyl group, p-tolyl group, p-hydroxyphenyl group, p-methoxyphenyl group, mesityl group, o-cumenyl group, 2,3-xylyl group, 2,4-xylyl group, 2,5-xylyl group, 2,6-xylyl group, 3,4-xylyl group, 3,5-xylyl group, p-fluorophenyl group, p-trifluoromethylphenyl group, p-chlorophenyl group, p-bromophenyl group and p-iodophenyl group.

As the monovalent heterocyclic organic group having the number of atoms of 4-30, replaced with the above substituent, it is possible to mention, for example, 2-bromofuryl group, 3-methoxythienyl group, 3-bromotetrahydropyranyl group, 4-methoxytetrahydropyranyl group, 4-methoxytetrahydrothiopyranyl group and the like.

A monovalent onium cation moiety represented by “M+” can be produced according to a general method discussed by Advances in Polymer Science, Vol. 62, p. 1-48 (1984), for example.

A preferable monovalent onium cation can be exemplified by sulfonium cations represented by the following formulas (3-1) to (3-64) and iodonium cations represented by the following formulas (4-1) to (4-39).

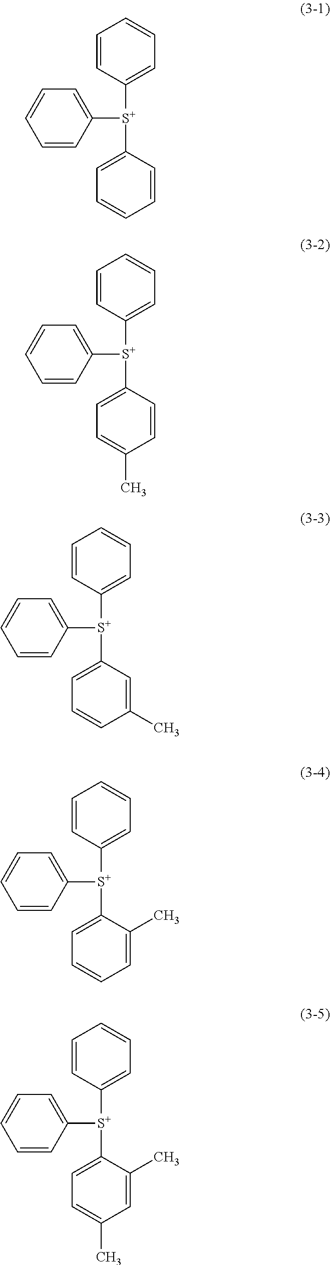 [SMILES: c1ccc([S+](c2ccccc2)c2ccccc2)cc1 ; Cc1ccc([S+](c2ccccc2)c2ccccc2)cc1 ; Cc1cccc([S+](c2ccccc2)c2ccccc2)c1 ; Cc1ccccc1[S+](c1ccccc1)c1ccccc1 ; Cc1ccc([S+](c2ccccc2)c2ccccc2)c(C)c1]

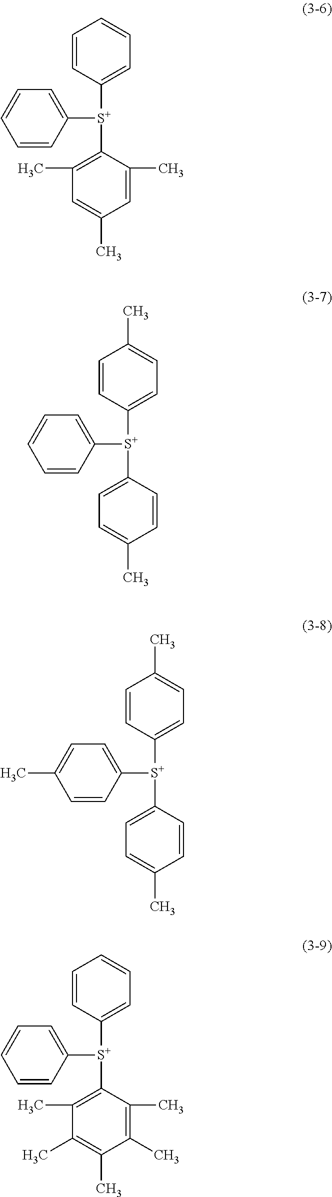

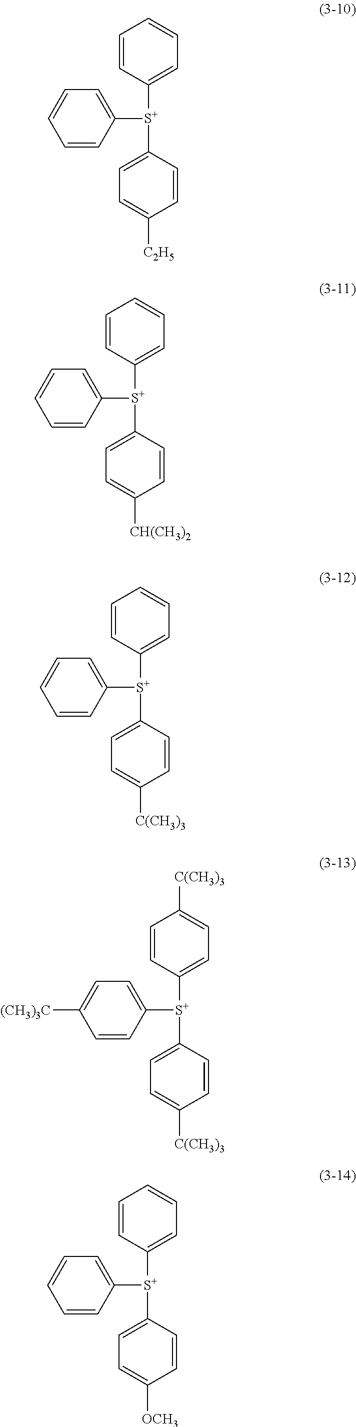 [SMILES: CCc1ccc([S+](c2ccccc2)c2ccccc2)cc1 ; CC(C)c1ccc([S+](c2ccccc2)c2ccccc2)cc1 ; CC(C)(C)c1ccc([S+](c2ccccc2)c2ccccc2)cc1 ; CC(C)(C)c1ccc([S+](c2ccc(C(C)(C)C)cc2)c2ccc(C(C)(C)C)cc2)cc1 ; COc1ccc([S+](c2ccccc2)c2ccccc2)cc1]

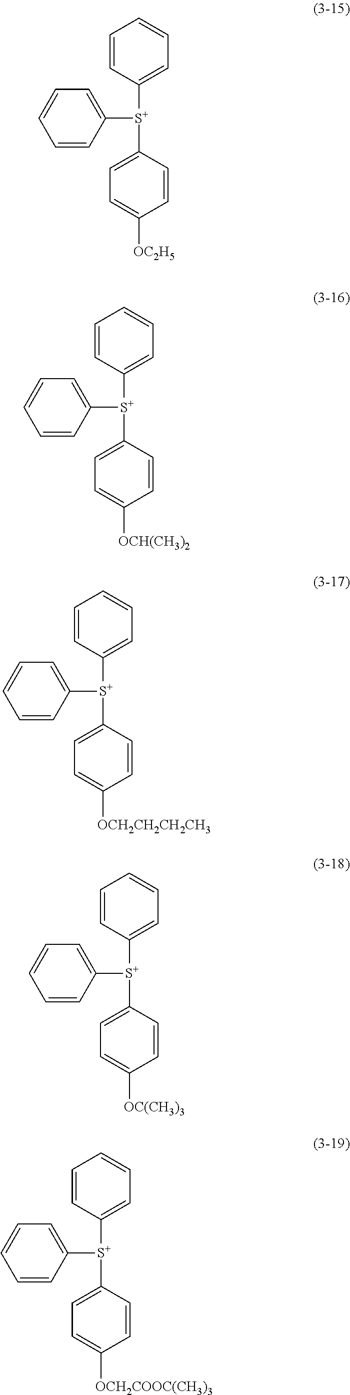

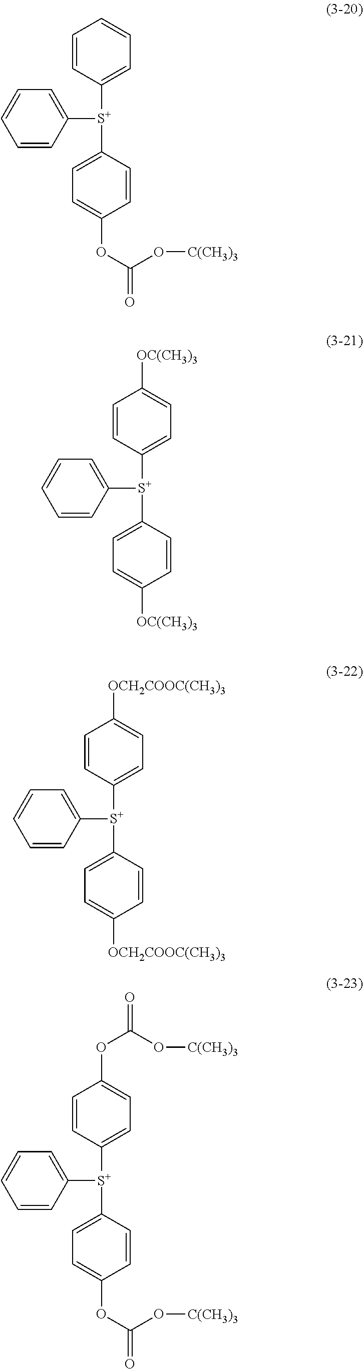

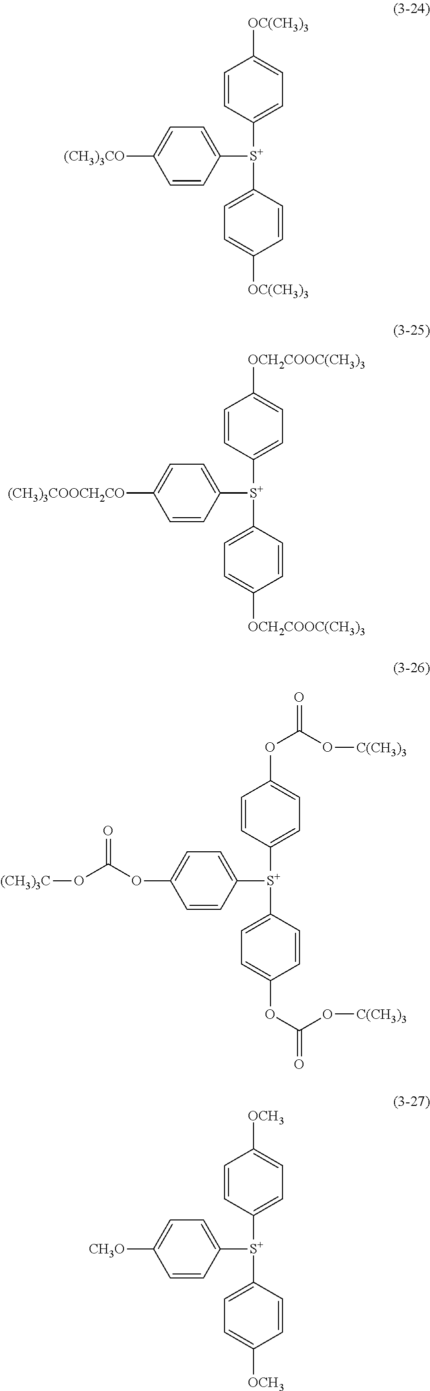

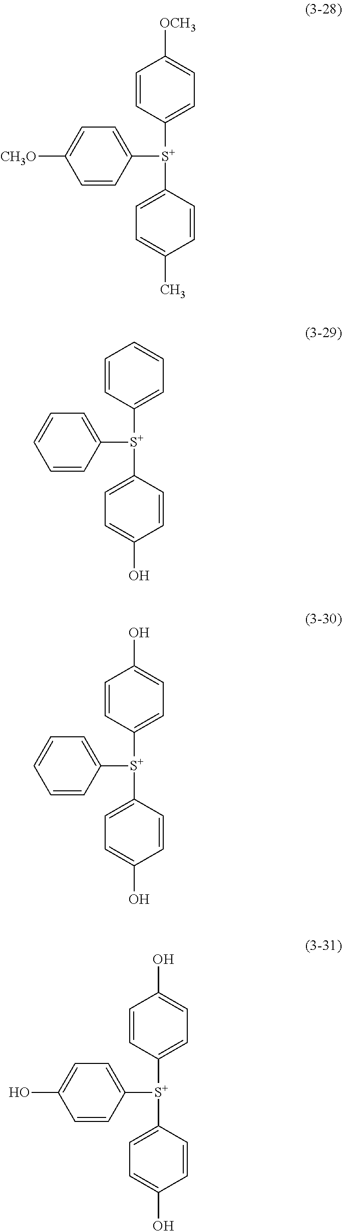

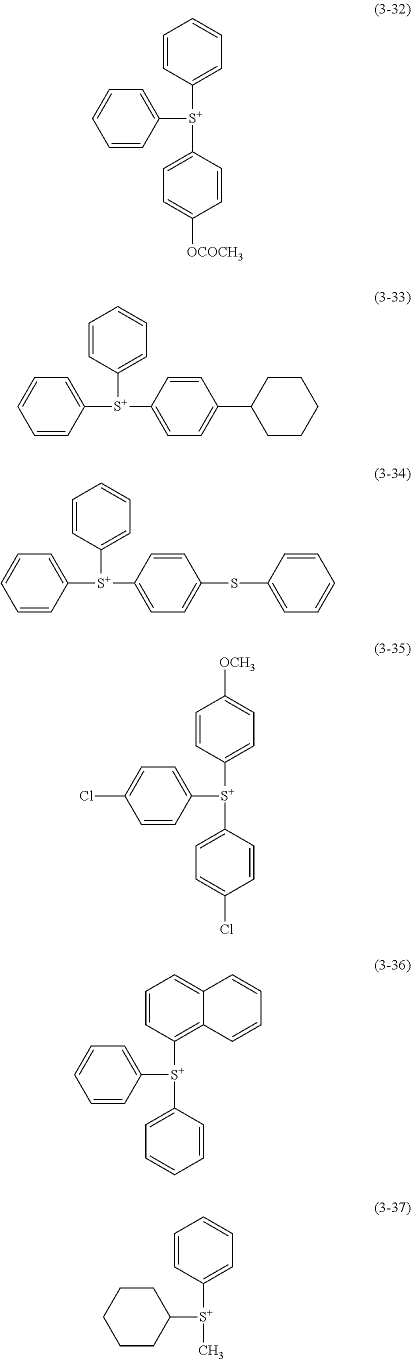

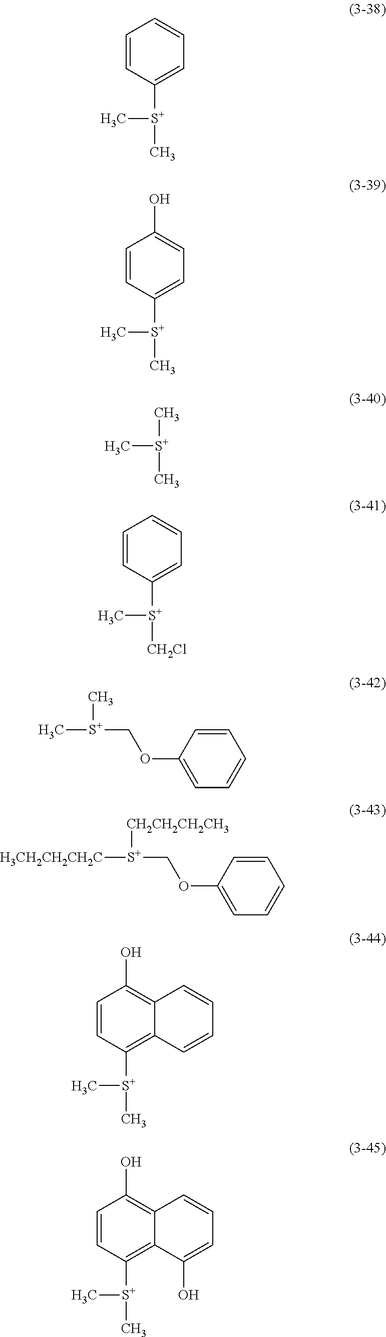

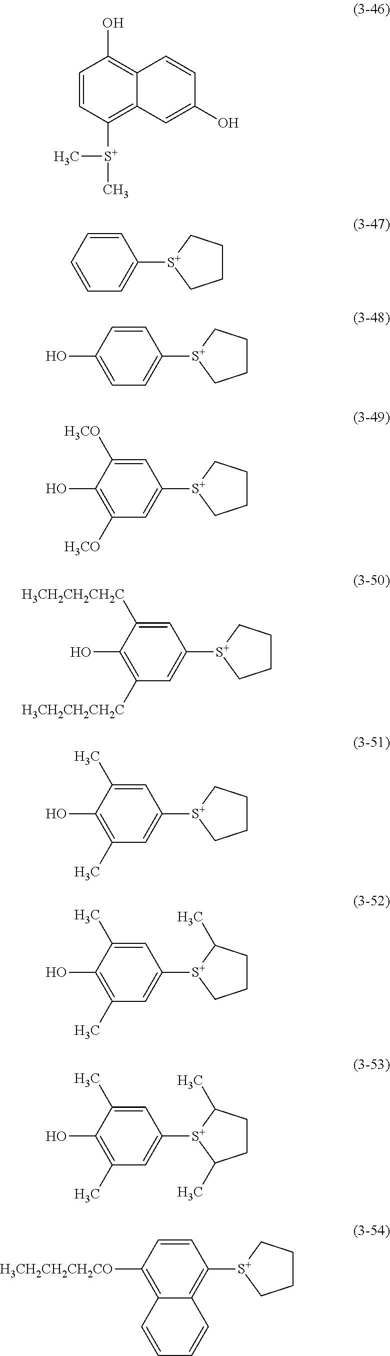

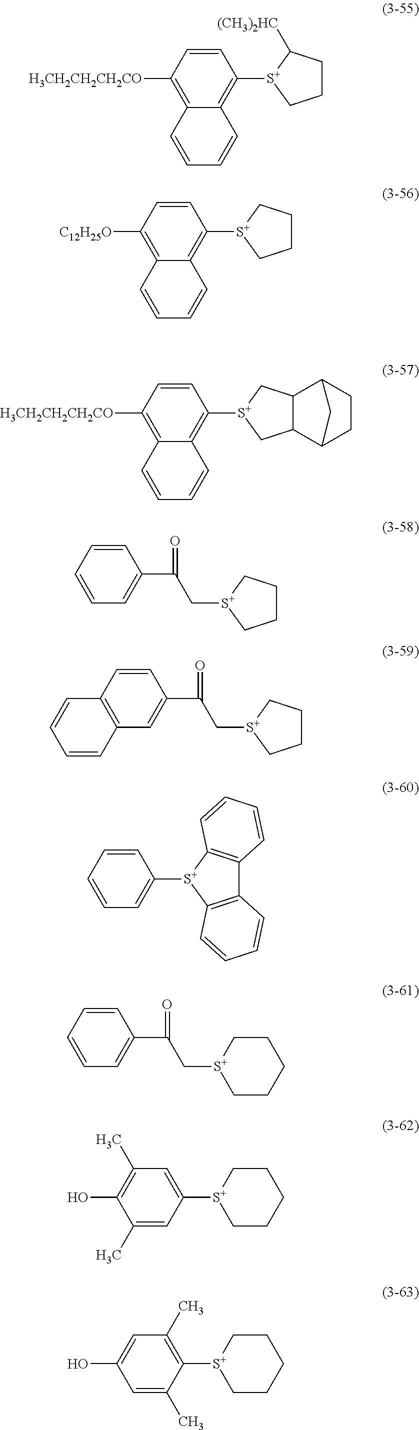

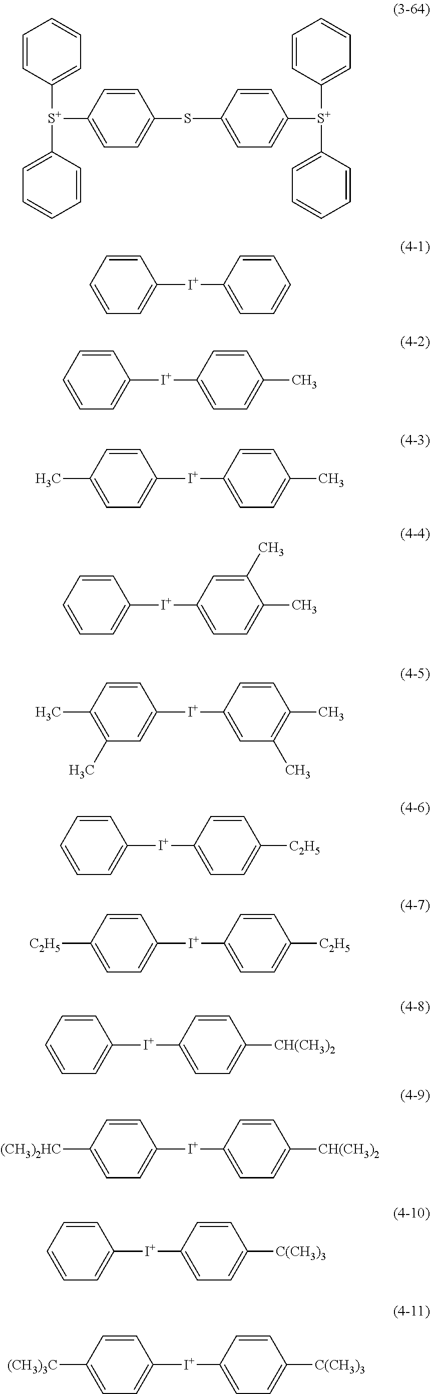

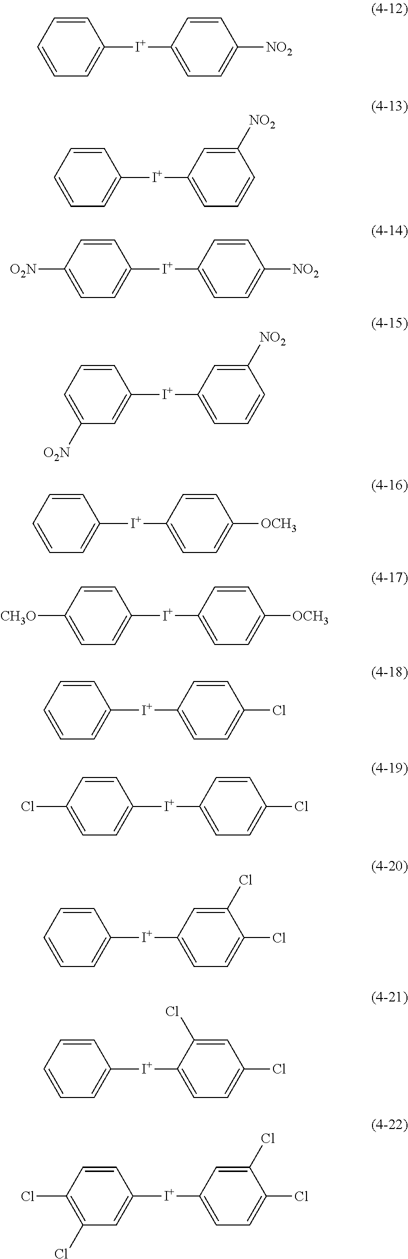

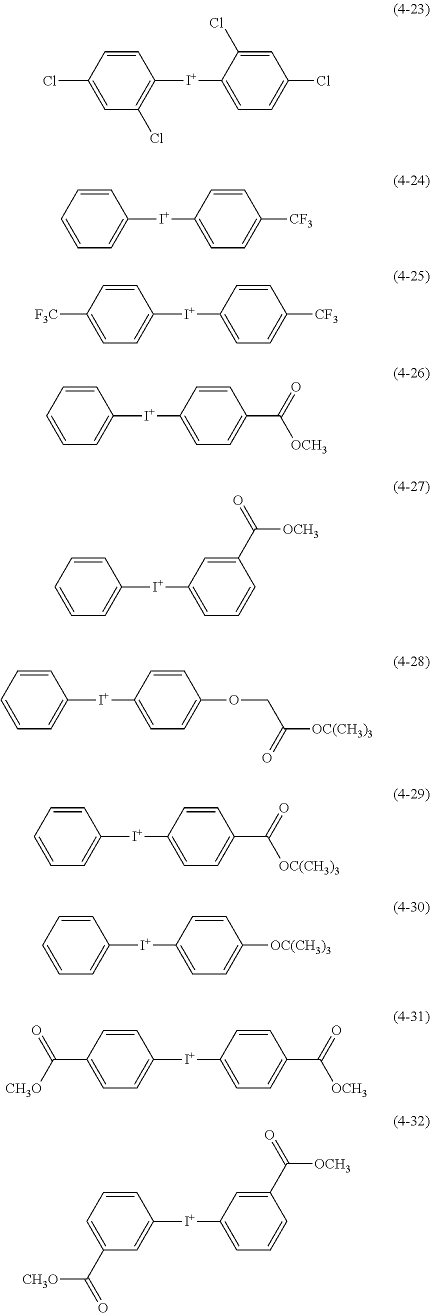

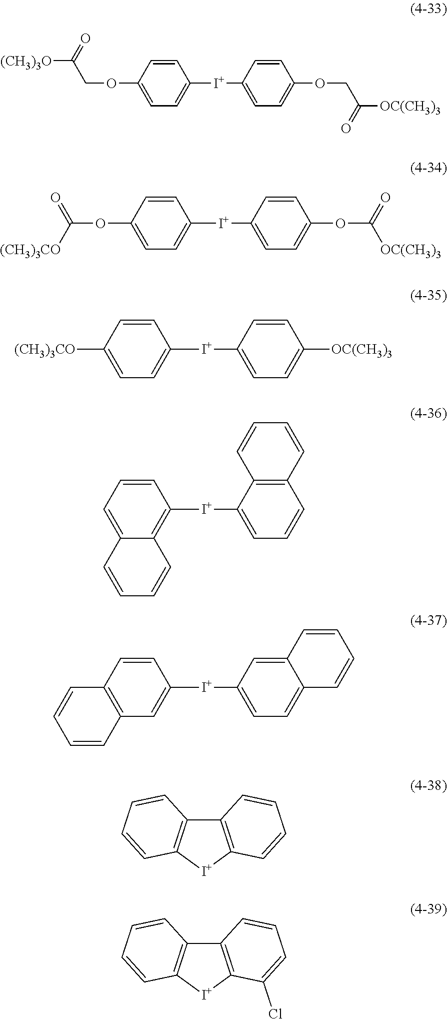

Of these monovalent onium cations, it is preferable to use a sulfonium cation represented by the formula (3-1), the formula (3-2), the formula (3-6), the formula (3-8), the formula (3-13), the formula (3-19), the formula (3-25), the formula (3-27), the formula (3-29), the formula (3-51) or the formula (3-54), an iodonium cation represented by the formula (4-1) or the formula (4-11), or the like, and it is particularly preferable to use a triphenylsulfonium cation represented by the formula (3-1).

### 6. Other Repeating Units

Now, a monomer providing the polymer of the present invention with other repeating units will be discussed.

As concrete examples of the monomer, it is possible to cite maleic anhydride, acrylic esters, fluorine-containing acrylic esters, methacrylic esters, fluorine-containing methacrylic esters, styrene-based compounds, fluorine-containing styrene-based compounds, vinyl ethers, fluorine-containing vinyl ethers, allyl ethers, fluorine-containing allyl ethers, olefins, fluorine-containing olefins, norbornene compounds, fluorine-containing norbornene compounds, sulfur dioxide, vinyl silanes, vinyl sulfonic acids, and vinyl sulfonic acid esters. It is possible to use not only one kind but also one or more kinds of the monomers as needed.

Though the acrylic esters and the methacrylic esters can be used with no particular limitation in terms of ester side chain, it is possible to use known compounds exemplified by: alkyl esters of acrylic acid or methacrylic acid such as methyl acrylate, methyl methacrylate, ethyl acrylate, ethyl methacrylate, n-propyl acrylate, n-propyl methacrylate, isopropyl acrylate, isopropyl methacrylate, n-butyl acrylate, n-butyl methacrylate, isobutyl acrylate, isobutyl methacrylate, n-hexyl acrylate, n-hexyl methacrylate, n-octyl acrylate, n-octyl methacrylate, 2-ethylhexyl acrylate, 2-ethylhexyl methacrylate, lauryl acrylate, lauryl methacrylate, 2-hydroxyethyl acrylate, 2-hydroxyethyl methacrylate, 2-hydroxypropyl acrylate, 2-hydroxypropyl methacrylate, 3-oxocyclohexyl acrylate, 3-oxocyclohexyl methacrylate, adamantyl acrylate, adamantyl methacrylate, hydroxyadamantyl acrylate, hydroxyadamantyl methacrylate, cyclohexyl acrylate, cyclohexyl methacrylate, tricyclodecanyl acrylate, tricyclodecanyl methacrylate and the like; acrylates or methacrylates containing ethylene glycol, propylene glycol or tetramethylene glycol group; unsaturated amides such as acrylamide, methacrylamide, N-methylol acrylamide, N-methylol methacrylamide, diacetone acrylamide and the like; vinyl silanes and acrylic or methacrylic esters containing acrylonitrile, methacrylonitrile or alkoxysilane; the above-mentioned acrylate compounds having a cyano group at its α-position; and similar compounds such as maleic acid, fumaric acid and maleic anhydride.

As a fluorine-containing acrylic ester or a fluorine-containing methacrylic ester, it is preferable to use: a monomer containing a fluorine atom or a group having fluorine atom, at α-position of acryl; or an acrylic ester or a methacrylic ester comprised of a substituent having fluorine atom at its ester moiety. It is also preferable to use a fluorine-containing compound which contains fluorine at both α-position and the ester moiety. Furthermore, a cyano group may be introduced into α-position. For example, as a monomer having α-position into which a fluorine-containing alkyl group is introduced, there may be adopted a monomer obtained by providing a trifluoromethyl group, trifluoroethyl group, nonafluoro-n-butyl group or the like to α-position of the non-fluorine-containing acrylic or methacrylic ester.

On the other hand, monomers containing fluorine at its ester moiety are acrylic or methacrylic esters that have: a fluorine alkyl (perfluoroalkyl group or fluoroalkyl group) as ester moiety; or an unit at which ester moiety a cyclic structure and a fluorine atom are coexistent. The unit is exemplified by those in which the cyclic structure is substituted with a fluorine atom, a trifluoromethyl group, a hexafluoroisopropyl hydroxyl group or the like, such as a fluorine-containing benzene ring, a fluorine-containing cyclopentane ring, a fluorine-containing cyclohexane ring, a fluorine-containing cycloheptane ring and the like. Additionally, acrylic or methacrylic esters of which ester moiety is a fluorine-containing t-butyl ester group are also usable. It is also possible to use a monomer obtained by combining these fluorine-containing functional groups and the fluorine-containing alkyl group of α-position. If particularly representative ones of such units are exemplified in the form of monomer, it is possible to cite 2,2,2-trifluoroethyl acrylate, 2,2,3,3-tetrafluoropropyl acrylate, 1,1,1,3,3,3-hexafluoroisopropyl acrylate, heptafluoroisopropyl acrylate, 1,1-dihydroheptafluoro-n-butyl acrylate, 1,1,5-trihydrooctafluoro-n-pentyl acrylate, 1,1,2,2-tetrahydrotridecafluoro-n-octyl acrylate, 1,1,2,2-tetrahydroheptadecafluoro-n-decyl acrylate, 2,2,2-trifluoroethyl methacrylate, 2,2,3,3-tetrafluoropropyl methacrylate, 1,1,1,3,3,3-hexafluoroisopropyl methacrylate, heptafluoroisopropyl methacrylate, 1,1-dihydroheptafluoro-n-butyl methacrylate, 1,1,5-trihydrooctafluoro-n-pentyl methacrylate, 1,1,2,2-tetrahydrotridecafluoro-n-octyl methacrylate, 1,1,2,2-tetrahydroheptadecafluoro-n-decyl methacrylate, perfluorocyclohexylmethyl acrylate, perfluorocyclohexylmethyl methacrylate, 6-[3,3,3-trifluoro-2-hydroxy-2-(trifluoromethyl)propyl]bicyclo[2,2,1]hept-2-yl acrylate, 6-[3,3,3-trifluoro-2-hydroxy-2-(trifluoromethyl)propyl]bicyclo[2,2,1]hept-2-yl 2-(trifluoromethyl)acrylate, 6-[3,3,3-trifluoro-2-hydroxy-2-(trifluoromethyl)propyl]bicyclo[2,2,1]hept-2-yl methacrylate, 1,4-bis(1,1,1,3,3,3-hexafluoro-2-hydroxyisopropyl)cyclohexyl acrylate, 1,4-bis(1,1,1,3,3,3-hexafluoro-2-hydroxyisopropyl)cyclohexyl methacrylate, and 1,4-bis(1,1,1,3,3,3-hexafluoro-2-hydroxyisopropyl)cyclohexyl 2-trifluoromethyl acrylate.

As a styrene-based compound and a fluorine-containing styrene-based compound, it is possible to use styrene, a fluorine-containing styrene, hydroxystyrene and the like. More specifically, it is possible to use: a styrene where hydrogen of an aromatic ring is substituted with a fluorine atom or trifluoromethyl group, such as pentafluorostyrene, trifluoromethylstyrene, bistrifluoromethylstyrene and the like; or a styrene where hydrogen of the aromatic ring is substituted with a hexafluoroisopropyl hydroxyl group or a functional group obtained by protecting the hydroxyl group. Additionally, it is also possible to use the above-mentioned styrene having α-position to which halogen, alkyl group or a fluorine-containing alkyl group is bonded, styrene having a perfluorovinyl group and, or the like.

As vinyl ethers, fluorine-containing vinyl ethers, allyl ethers and fluorine-containing allyl ethers, it is possible to use alkyl vinyl ethers and alkyl allyl ethers which may have a methyl group, ethyl group, propyl group, butyl group or a hydroxyl group (such as hydroxyethyl group, hydroxybutyl group and the like), etc. Additionally, it is also possible to use: cyclic-type vinyls having a cyclohexyl group, norbornyl group or aromatic ring or having hydrogen or a carbonyl bond in its cyclic structure; allyl ethers; and fluorine-containing vinyl ethers and fluorinated allyl ethers in which some or all of hydrogens of the above-mentioned functional groups are substituted with fluorine atom(s).

Incidentally, it is possible in the present invention to use vinyl esters, vinyl silanes, olefins, fluorine-containing olefins, norbornene compounds, fluorine-containing norbornene compounds and other compounds having a polymerizable unsaturated bond, with no particular limitation.

The olefins can be exemplified by ethylene, propylene, isobutene, cyclopentene and cyclohexene. The fluorine-containing olefins can be exemplified by vinyl fluoride, vinylidene fluoride, trifluoroethylene, chlorotrifluoroethylene, tetrafluoroethylene, hexafluoropropylene and hexafluoroisobutene.

The norbornene compounds and the fluorine-containing norbornene compounds are norbornene monomers having a single or plurality of nucleus structures. In this case, as the norbornene monomers, it is possible to cite monomers obtained by reacting an unsaturated compound with cyclopentadiene or cyclohexadiene. For example, it is possible to cite norbornene compounds produced by Diels Alder addition reaction between cyclopentadiene or cyclohexadiene and unsaturated compounds such as a fluorine-containing olefin, allyl alcohol, a fluorine-containing allyl alcohol, homoallyl alcohol, a fluorine-containing homoallyl alcohol, acrylic acid, α-fluoroacrylic acid, α-trifluoromethylacrylic acid, methacrylic acid, acrylic ester, methacrylic ester, a fluorine-containing acrylic ester, a fluorine-containing methacrylic ester, 2-(benzoyloxy)pentafluoropropane, 2-(methoxyethoxymethyloxy)pentafluoropropene, 2-(tetrahydroxypyranyloxy)pentafluoropropene, 2-(benzoyloxy)trifluoroethylene, 2-(methoxymethyloxy)trifluoroethylene and the like. The norbornene compounds can be exemplified by 3-(5-bicyclo[2,2,1]hepten-2-yl)-1,1,1-trifluoro-2-(trifluoromethyl)-2-propanol.

### 7. Polymer of the Present Invention and Synthesis Method Thereof.

Then, a polymer according to the present invention and a synthesis method therefor will be discussed.

The polymer according to the present invention may be comprised of repeating units of two or more monomers. The ratio can be determined with no particular limitation, but ranges as discussed below are preferably adopted.

The polymer according to the present invention may contain: the repeating unit represented by the general formula (1) within a range of not lower than 1 mol % and not higher than 100 mol %, more preferably not lower than 5 mol % and not higher than 90 mol %; and the repeating unit having an acid-releasable group within a range of not lower than 1 mol % and not higher than 100 mol %, more preferably not lower than 5 mol % and not higher than 80 mol %, and much more preferably not lower than 10 mol % and not higher than 60 mol %. In the case where the content of the repeating unit having an acid-releasable group is smaller than 1 mol %, a change in solubility exhibited in alkali developing solution by exposure is so slight that contrast to be formed by patterning cannot be expected.

In this case, as the repeating unit having an acid-releasable group, it is possible to use a general monomer and it is also possible to use one obtained by deriving the monomer represented by the general formula (1) of the present invention to an acid-releasable monomer. Alternatively, one provided with an acid-releasable group after polymerization is also usable. Furthermore, a repeating unit having an HFIP group, a repeating unit having an adhesive group, a repeating unit having a salt and a repeating unit having other functional group may be contained at a remaining moiety.

In this case, the content of the repeating unit having an adhesive group is preferably not lower than 5 mol % and not higher than 90 mol % relative to the total number of moles (a total of all kinds of repeating units that constitute the polymer). The content of lower than 5 mol % does not provide the effect of improving the adhesiveness to a substrate. Additionally, from the viewpoint of the solubility in a developing solution when used as a resist, the content exceeding 90 mol % makes it difficult to solve the polymer in a developing solution.

A repeating unit having a salt is useful as a radiation-sensitive acid generator contained in a radiation-sensitive resin composition. The content thereof is not lower than 0.01 mol % and not higher than 95 mol %. If the content is lower than 0.01 mol %, the polymer becomes poor in effect of improving the contrast as a radiation-sensitive resist, and it is not necessary to add the repeating unit in an amount exceeding 95 mol %.

A synthesis method for the polymer according to the present invention is not particularly limited insofar as the method is a generally usable one, but radical polymerization, ion polymerization or the like is preferable. In some cases it is also possible to employ coordination anion polymerization, living anion polymerization, cation polymerization, ring-opening metathesis polymerization, vinylene polymerization or the like.

Radical polymerization may be conducted by a known synthesis method such as bulk polymerization, solution polymerization, suspension polymerization, emulsion polymerization and the like in the presence of a radical polymerization initiator or a radical initiating source, with a batch-wise, semi-continuous or continuous operation.

The radical polymerization initiator is not particularly limited. As its examples, azo compounds, peroxide compounds and redox compounds are cited. The particularly preferable examples are azobisisobutyronitrile, t-butylperoxypivalate, di-t-butylperoxide, i-butyrylperoxide, lauroylperoxide, succinic acid peroxide, dicinnamylperoxide, di-n-propylperoxydicarbonate, t-butylperoxyallyl monocarbonate, benzoyl peroxide, hydrogen peroxide, ammonium persulfate and the like.

A reaction vessel used for the polymerization reaction is not particularly limited. Additionally, a polymerization solvent may be used in the polymerization reaction. As the polymerization solvent, one that does not interfere with radical polymerization is preferable, and representative examples thereof are: ester-based ones such as ethyl acetate, n-butyl acetate and the like; ketone-based ones such as acetone, methyl isobutyl ketone and the like; hydrocarbon-based ones such as toluene, cyclohexane and the like; and alcohol-based solvents such as methanol, isopropyl alcohol, ethylene glycol monomethyl ether and the like. Additionally, it is also possible to use various types of solvents, such as water, ether-based ones, cyclic ether-based ones, fluorohydrocarbon-based ones, aromatic ones and the like. These solvents may be used singly or in combination of not less than two kinds of them. Additionally, a molecular weight adjusting agent such as mercaptan may be used together therewith. The reaction temperature in the copolymerization reaction is suitably changed according to the radical polymerization initiator or radical polymerization initiating source, and is preferably not lower than 20° C. and not higher than 200° C. in general, particularly preferably within a range of not lower than 30° C. and not higher than 140° C.

On the other hand, ring-opening metathesis polymerization is required only to use a transition metal catalyst of the groups IV to VII and conducted by a known method in the presence of a solvent.

A polymerization catalyst used for the polymerization reaction is not particularly limited and exemplified by Ti-based, V-based, Mo-based and W-based catalysts. In particular, titanium(IV) chloride, vanadium(IV) chloride, vanadium trisacetylacetonate, vanadium bisacetylacetonatedichloride, molybdenum(VI) chloride, tungsten(VI) chloride and the like are preferable. The amount of the catalyst is within a range of not lower than 0.001 mol % and not higher than 10 mol %, preferably not lower than 0.01 mol % and not higher than 1 mol % relative to the used monomer.

As a co-catalyst of the above-mentioned polymerization catalyst, alkylaluminum, alkyltin and the like are cited. In particular, it can be exemplified by: aluminum-based ones including trialkylaluminums such as trimethylaluminum, triethylaluminum, tripropylaluminum, triisopropylaluminum, triisobutylaluminum, tri-2-methylbutylaluminum, tri-3-methylbutylaluminum, tri-2-methylpentylaluminum, tri-3-methylpentylaluminum, tri-4-methylpentylaluminum, tri-2-methylhexylaluminum, tri-3-methylhexylaluminum, trioctylaluminum and the like, dialkylaluminum halides such as dimethylaluminum chloride, diethylaluminum chloride, diisopropylaluminum chloride, diisobutylaluminum chloride and the like, monoalkylaluminum halides such as methylaluminum dichloride, ethylaluminum dichloride, ethylaluminum diiodide, propylaluminum dichloride, isopropylaluminum dichloride, butylaluminum dichloride, isobutylaluminum dichloride and the like, and alkylaluminum sesquichlorides such as methylaluminum sesquichloride, ethylaluminum sesquichloride, propylaluminum sesquichloride, isobutylaluminum sesquichloride and the like; tetra-n-butyltin; tetraphenyltin; triphenylchlorotin and the like. The amount of the co-catalyst is 100 equivalents or less, preferably 30 equivalents or less by molar ratio relative to the transition metal catalyst.

The polymerization solvent will do unless it interferes with the polymerization reaction, and representative examples thereof are: aromatic hydrocarbon-based ones such as benzene, toluene, xylene, chlorobenzene, dichlorobenzene and the like; hydrocarbon-based ones such as hexane, heptane, cyclohexane and the like; and halogenated hydrocarbons such as carbon tetrachloride, chloroform, methylene chloride, 1,2-dichloroethane and the like. Additionally, these solvents may be used singly or in combination of two or more kinds. The reaction temperature is preferably not lower than −70° C. and not higher than 200° C. in general, particularly preferably within a range of not lower than −30° C. and not higher than 60° C.

Vinylene polymerization is required only to use a transition metal catalyst of the group VIII such as iron, nickel, rhodium, palladium, platinum and the like, or a metal catalyst of the groups IVB to VIB such as zirconium, titanium, vanadium, chromium, molybdenum, tungsten and the like in the presence of a co-catalyst. It may be conducted by a known method in the presence of a solvent.

The polymerization catalyst for vinylene polymerization is not particularly limited but, as particularly preferable examples, it is possible to cite: transition metal compounds of the group VIII, such as iron(II) chloride, iron(III) chloride, iron(II) bromide, iron(III) bromide, iron(II) acetate, iron(III) acetylacetonate, ferrocene, nickelocene, nickel(II) acetate, nickel bromide, nickel chloride, dichlorohexylnickel acetate, nickel lactate, nickel oxide, nickel tetrafluoroborate, bis(cyclopentadienyl)nickel, nickel(II) hexafluoroacetylacetonatetetrahydrate, nickel(II) trifluoroacetylacetonatedihydrate, nickel(II) acetylacetonatetetrahydrate, rhodium(III) chloride, rhodium tris(triphenylphosphine)trichloride, palladium(II) bis(trifluoroacetate), palladium(II) bis(acetylacetonate), palladium(II) 2-ethylhexanoate, palladium(II) bromide, palladium(II) chloride, palladium(II) iodide, palladium(II) oxide, monoacetonitriletrigtriphenylphosphine)palladium tretrafluoroborate, tetrakis(acetonitrile)palladium(II) tetrafluoroborate, dichlorobis(acetonitrile)palladium(II), dichlorobis(triphenylphosphine)palladium(II), dichlorobis(benzonitrile)palladium(II), palladium acetylacetonate, palladium bis(acetonitrile)dichloride, palladium bis(dimethylsulfoxide)dichloride, platinum bis(triethylphosphine)hydrobromide and the like; and transition metal compounds of the groups IVB to VIB, such as vanadium(IV) chloride, vanadium trisacetylacetonate, vanadium bisacetylacetonatedichloride, trimethoxy(pentamethylcyclopentadienyl)titanium(IV), bis(cyclopentadienyl)titanium dichloride, bis(cyclopentadienyl)zirconium dichloride and the like. The amount of the catalyst is within a range of not lower than 0.001 mol % and not higher than 10 mol %, preferably not lower than 0.01 mol % and not higher than 1 mol % relative to the used monomer.

As a co-catalyst of the above-mentioned polymerization catalyst, alkylaluminoxane, alkylaluminum and the like are cited. In particular, it can be exemplified by: methylaluminoxane (MAO); trialkylaluminums such as trimethylaluminum, triethylaluminum, tripropylaluminum, triisopropylaluminum, triisobutylaluminum, tri-2-methylbutylaluminum, tri-3-methylbutylaluminum, tri-2-methylpentylaluminum, tri-3-methylpentylaluminum, tri-4-methylpentylaluminum, tri-2-methylhexylaluminum, tri-3-methylhexylaluminum, trioctylaluminum and the like; dialkylaluminum halides such as dimethylaluminum chloride, diethylaluminum chloride, diisopropylaluminum chloride, diisobutylaluminum chloride and the like; monoalkylaluminum halides such as methylaluminum dichloride, ethylaluminum dichloride, ethylaluminum diiodide, propylaluminum dichloride, isopropylaluminum dichloride, butylaluminum dichloride, isobutylaluminum dichloride and the like; and alkylaluminum sesquichlorides such as methylaluminum sesquichloride, ethylaluminum sesquichloride, propylaluminum sesquichloride, isobutylaluminum sesquichloride and the like. In the case of methylaluminoxane, the amount of the co-catalyst is not lower than 50 equivalents and not higher than 500 equivalents in terms of Al conversion. In the case of other alkylaluminums, the amount of the co-catalyst is 100 equivalents or less, preferably 30 equivalents or less by molar ratio relative to the transition metal catalyst.

Additionally, the polymerization solvent for vinylene polymerization will do unless it interferes with the polymerization reaction, and representative examples thereof are aromatic hydrocarbon-based ones such as benzene, toluene, xylene, chlorobenzene, dichlorobenzene and the like, hydrocarbon-based ones such as hexane, heptane, nonane, decane, cyclohexane and the like, ketone-based ones such as acetone, methyl ethyl ketone, methyl isopropyl ketone, methyl isobutyl ketone, cyclohexanone, cyclopentanone and the like, ester-based ones such as ethyl acetate, butyl acetate and the like, alcohol-based solvents such as methanol, ethanol, propanol, isopropanol, butanol, isobutanol, pentanol, hexanol, nonanol, octanol, 1-octanol, 2-octanol, 3-octanol, 4-methyl-2-pentanol,ethylene glycol and the like, halogenated hydrocarbon-based ones such as carbon tetrachloride, chloroform, methylene chloride, 1,2-dichloroethane and the like, diethyl ether, diisopropyl ether, tetrahydrofuran, diglyme, propylene glycol monomethyl ether acetate (PEGMEA), propylene glycol monoethyl ether acetate, propylene glycol monoethyl ether, propylene glycol monomethyl ether (PEGME), propylene glycol diacetate, propylene glycol monoethyl ether, ethyl lactate (EL), dimethylformamide, N-methylpyrolidone, N-cyclohexylpyrolidone and the like. Additionally, these solvents may be used singly or in combination of two or more kinds. The reaction temperature is preferably within a range of not lower than −70° C. and not higher than 200° C. in general, particularly preferably within a range of not lower than −40° C. and not higher than 80° C.

As a method of removing a medium (an organic solvent or water) from a solution or dispersion liquid of the thus obtained polymer according to the present invention, any known method can be used. If these are exemplified, methods such as reprecipitation filtration, heating distillation under reduced pressure and the like are cited.

Concerning the number average molecular weight of the polymer according to the present invention, a range of not lower than 1,000 and not higher than 100,000, preferably a range of not lower than 3,000 and not higher than 50,000 is appropriate.

### 8. Resist Material According to the Present Invention

Hereinafter, a resist material according to the present invention will be discussed.

The present invention includes a resist material of Invention 4, the resist material being characterized by containing a polymer as discussed in any one of Inventions 1 to 3.

Furthermore, the present invention includes a resist material of Invention 5, the resist material being characterized in that the resist material of Invention 4 further contains at least one kind of an acid generator, a basic compound and an organic solvent.

The polymer according to the present invention is preferably used as a positive-type photosensitizing resist material in particular. The present invention provides a resist material containing a polymer of Inventions 1 to 3 and particularly provides a positive-type resist material. As the resist material in this case, those containing: (A) the above-mentioned polymer as a base resin, (B) a photoacid generator, (C) a basic compound and (D) a solvent are preferable. Additionally, the resist material may contain (E) a surfactant, as necessary. Now (B) to (C) will be independently discussed.

### 8-1. “(B) Photoacid Generator”

A photoacid generator serves as a photosensitizer having a function of generating acid, by ultraviolet or extreme ultraviolet irradiation. A photoacid generator used for the resist material according to the present invention is not particularly limited, and therefore it is possible to use an arbitrary one selected from those used as acid generators for chemically amplified resists insofar as it is soluble in a solvent. Such acid generators can be exemplified by onium sulfonate such as iodonium sulfonate, sulfonium sulfonate and the like, sulfonic ester, N-imidesulfonate, N-oximesulfonate, o-nitrobenzyl sulfonate, trismethane sulfonate of pyrogallol and the like.

Acids to be generated from these photoacid generators by the action of light include alkanesulfonic acid and aryl sulfonate, the alkanesulfonic acid and aryl sulfonate being partially or entirely fluorinated. A photoacid generator which generates a partially or entirely fluorinated alkanesulfonic acid is effective because it has a sufficient acid strength even against protective groups hard to deblock. Concretely, it is possible to cite triphenylsulfonium trifluoromethanesulfonate, triphenylsulfonium perfluoro-n-octanesulfonate and the like.

### 8-2. “(C) Basic Compound”

It is possible to mix a basic compound into the resist material of the present invention. The basic compound has the function of suppressing the diffusion velocity exhibited when acid generated by an acid generator diffuses into a resist film, with which the diffusion length of the acid is adjusted to improve a resist pattern shape.

Such a basic compound is exemplified by aliphatic amine, aromatic amine, heterocyclic amine, aliphatic polycyclic amine and the like. Secondary or tertiary aliphatic amine is particularly preferable, and alkyl alcohol amine is more preferably adopted.

Concretely, it is possible to cite trimethylamine, triethylamine, tripropylamine, tributylamine, tripentylamine, trihexylamine, triheptylamine, trioctylamine, trinonylamine, tridecanylamine, tridodecylamine, dimethylamine, diethylamine, dipropylamine, dibutylamine, dipentylamine, dihexylamine, diheptylamine, dioctylamine, dinonylamine, didecanylamine, didodecylamine, dicyclohexylamine, methylamine, ethylamine, propylamine, butylamine, pentylamine, hexylamine, heptylamine, octylamine, nonylamine, decanylamine, dodecylamine, diethanolamine, triethanolamine, diisopropanolamine, triisopropanolamine, dioctanolamine, trioctanolamine, aniline, pyridine, picoline, lutidine, bipyridine, pyrrole, piperidine, piperazine, indole and hexamethylenetetramine. These compounds may be used singly or in combination of two or more kinds. Additionally, the mixing amount thereof is preferably not lower than 0.001 part by weight and not higher than 2 parts by weight relative to 100 parts by weight of a polymer, more preferably not lower than 0.01 part by weight and not higher than 1 part by weight relative to 100 parts by weight of the polymer. When the mixing amount is smaller than 0.001 part by weight, the effect as additive is not sufficiently provided. When the mixing amount exceeds 2 parts by weight, resolution performance and sensitivity are sometimes reduced.

### 8-3. “(D) Solvent”

A solvent used for the resist material of the present invention is required only to dissolve all of the components to be mixed to provide a uniform solution, and may be selected from conventional solvents for resist. Additionally, it is also possible to use two or more kinds of solvents in combination.

Concretely, it is possible to cite: ketones such as acetone, methyl ethyl ketone, cyclopentanone, cyclohexanone, methyl isobutyl ketone, methyl isopentyl ketone, 2-heptanone and the like; alcohols such as isopropanol, butanol, isobutanol, n-pentanol, isopentanol, tert-pentanol, 4-methyl-2-pentanol, 3-methyl-3-pentanol, 2,3-dimethyl-2-pentanol, n-hexanol, n-heptanol, 2-heptanol, n-octanol, n-decanol, s-amyl alcohol, t-amyl alcohol, isoamyl alcohol, 2-ethyl-1-butanol, lauryl alcohol, hexyl decanol, oleyl alcohol and the like; polyalcohols such as ethylene glycol, diethylene glycol, propylene glycol, dipropylene glycol, ethylene glycol monoacetate, diethylene glycol monoacetate, propylene glycol monoacetate, dipropylene glycol monoacetate, propylene glycol monomethyl ether, propylene glycol monoethyl ether, propylene glycol monopropyl ether, propylene glycol monobutyl ether, propylene glycol monomethyl ether acetate (PGMEA), propylene glycol monomethyl ether (PGME) and the like and these derivatives; esters such as methyl lactate, ethyl lactate (EL), methyl acetate, ethyl acetate, butyl acetate, methyl pyruvate, ethyl pyruvate, methyl methoxypropionate, ethyl ethoxypropionate and the like; aromatic solvents such as toluene, xylene and the like; ethers such as diethyl ether, dioxane, anisole, diisopropyl ether and the like; and fluoroine-based solvents such as chlorofluorocarbons, alternative chlorofluorocarbons, perfluoro compounds, hexafluoroisopropyl alcohol and the like. Furthermore, terpene-based petroleum naphtha solvents and paraffinic solvents, which serve as high-boiling-point weak solvents, are also usable for the purpose of increasing wettability at the time of application.

Of these, propylene glycol monomethyl ether acetate (PGMEA), propylene glycol monomethyl ether (PGME), ethyl lactate (EL) and cyclohexanone are particularly preferably adopted as the solvent for the resist material of the present invention, for the reason that the resist is provided excellently in solubility and stability.

The amount of the solvent to be mixed into a resist solution formed of the resist material of the present invention is not particularly limited; however, the solvent is used for preparing a resist solution such that the concentration of a solid content is preferably within a range of not lower than 3 mass % and not higher than 25 mass %, more preferably within a range of not lower than 5 mass % and not higher than 15 mass %. By adjusting the concentration of the solid content of the resist, it becomes possible to adjust the film thickness of a resin film to be formed.

Furthermore, the polymer of Inventions 1 to 3 is excellent in solubility in a wide variety of solvents, and it is worthy of note that the polymer dissolves in alcohol-based solvents having 5 to 20 carbon atoms among the above-mentioned alcohol-based solvents. As concrete examples of the alcohols, it is possible to cite n-pentanol, isopentanol, tert-pentanol, 4-methyl-2-pentanol, 3-methyl-3-pentanol, 2,3-dimethyl-2-pentanol, n-hexanol, n-heptanol, 2-heptanol, n-octanol, n-decanol, s-amyl alcohol, t-amyl alcohol, isoamyl alcohol, 2-ethyl-1-butanol, lauryl alcohol, hexyldecanol, oleyl alcohol and the like.

If taking the fact that resist materials used for general purposes do not dissolve in the alcohol-based solvents having 5 or more carbon atoms into account, a resist material of the present invention not only allows a wide use of solvents in a common resist pattern formation method but also useful as a resist material for a pattern formation method conducted according to double patterning process as discussed below, so as to be able to be developed as a resist material for a pattern formation method conducted according to double patterning process.

### 8-4. “(E) Surfactant”

To the resist material of the present invention, it is possible to add a surfactant as needed. As such a surfactant, any one or two or more kinds of a fluorine-based surfactant, silicon-based surfactant and a surfactant having both fluorine atom and silicon atom may be contained.

### 9. Pattern-Forming Method

Now, a pattern-forming method according to the present invention will be discussed.

A method of forming pattern by using the resist material of the present invention is accomplished by containing: a step of applying a resist material (a resist solution) to a substrate; a step of subjecting the substrate to heat treatment to form a resist film and then exposing the resist film to a high-energy ray that includes ultraviolet light and extreme ultraviolet light having a wavelength of 300 nm or less through a photomask by using an exposure apparatus; and a step of carrying out development by dissolving the resist film in a developing solution after subjecting the substrate to heat treatment, thereby forming a resist pattern. Any of these can be performed by adopting a known lithography technique.

For example, a resist material is applied onto a silicon wafer by spin coating technique to form a thin layer thereon, first of all. This is then subjected to prebaking on a hot plate at not lower than 60° C. and not higher than 200° C. for not shorter than 10 seconds and not longer than 10 minutes, preferably at not lower than 80° C. and not higher than 150° C. for not shorter than 30 seconds and not longer than 2 minutes. Then, a mask for forming a desired pattern is disposed, and a high-energy ray or electron beam such as ultraviolet rays, an excimer laser and X-rays is applied thereto in an amount of exposure of not smaller than 1 mJ/cm² and not larger than 200 mJ/cm², preferably not smaller than 10 mJ/cm² and not larger than 100 mJ/cm². Thereafter, heating treatment or a post exposure bake (which is a baking performed after exposure in order to diffuse acid generated by exposure into a resist, and may hereinafter be referred to as “PEB”) was conducted on a hot plate at not lower than 60° C. and not higher than 150° C. for not shorter than 10 seconds and not longer than 5 minutes, preferably at not lower than 80° C. and not higher than 130° C. for not shorter than 30 seconds and not longer than 3 minutes.

Furthermore, development was conducted in the use of a developing solution formed of an alkali aqueous solution (such as tetramethylammonium hydroxide (which may hereinafter be referred to as “TMAH”) and the like) of not lower than 0.1 mass % and not higher than 5 mass %, preferably not lower than 2 mass % and not higher than 3 mass %, for not shorter than 10 seconds and not longer than 3 minutes, preferably not shorter than 30 seconds and not longer than 2 minutes, by an existing method such as dipping (immersion) method, paddling method, spraying method and the like, with which a desired pattern is formed. Incidentally, the PEB may be conducted as necessary.

As the substrate used in the pattern-forming method of the present invention, it is possible to use a substrate formed of metal or glass, in addition to a silicon wafer. Additionally, the substrate may be formed having an organic or inorganic film thereon. For example, an antireflective film, or an underlayer of multilayer resist may be formed. Furthermore, a pattern may be formed thereon.

Incidentally, the resist material of the present invention does not particularly limit the light source and the wavelength to be used for exposure; however, the resist material of the present invention can be preferably used for lithographic micropatterning with KrF excimer laser, ArF excimer laser, F₂ excimer laser (wavelength: 157 nm), EUV, EB or X-rays. In particular, the resist material is preferably adopted for lithography using KrF excimer laser, ArF excimer laser or EUV.

### 10. Immersion Lithography

The resist of the present invention can be preferably used as a resist material for immersion lithography. More specifically, in immersion lithography where exposure is conducted upon filling a space defined between a resist and a lens with a medium having a larger refractive index than air, such as water and the like, the resist material of the present invention exhibits a high water resistance and has a compatibility with developing solution while providing a moderate water repellency. With this, it becomes possible to form a pattern finely.

Immersion lithography is such a lithography as to conduct exposure upon filling a space defined between a lens of an exposure apparatus and a substrate on which a resist film is formed with a liquid, in which exposure is performed upon filling the space defined between the lens and the substrate with water in the use of ArF excimer laser as a light source, for example. ArF excimer laser has a refractive index of 1.44 in water, so that the exposure light gives an incident angle to the substrate larger than that in air having a refractive index of 1. With this, it becomes possible to obtain a numerical aperture of not smaller than 1, so that the resolution performance on pattern is enhanced.

In immersion lithography, there are a case of using a topcoat serving as a protective film for pattern and a case of not using the same. The resist material of the present invention can be applied in both cases by adjusting the composition and the mixing ratio, and preferably employed as a resist for immersion lithography using KrF excimer laser or ArF excimer laser.

As a medium for immersion lithography using the resist of the present invention, it is possible to cite a fluorine-based solvent, a silicon-based solvent, a hydrocarbon-based solvent, a sulfur-containing solvent and the like, in addition to water. Thus the resist material of the present invention can widely be applied.

Double patterning is a technique for obtaining a high-density pattern, in which a pattern is divided into two low-density patterns (mask or reticle) and then the doubled patterns are exposed and developed, in order to obtain a desired pattern by lithography.

The resist material of the present invention can be used as a resist material for double patterning. As another embodiment of the present invention, there will be discussed a pattern-forming method according to double patterning; however, various pattern-forming methods are still under development, so that the method is not limited to the following. The resist material of the present invention can preferably be used also as a resist material for double patterning using KrF excimer laser or ArF excimer laser.

Incidentally, in double patterning using the resist material of the present invention, “a first resist film” refers to a resist film formed firstly in a pattern-forming process as discussed below, and additionally a resist pattern formed on the resist film by lithography is referred to as “a first resist pattern”. Likewise, “a second resist film” refers to a resist film formed on “the first resist pattern” by lithography to serve as a second layer, and additionally “a second resist pattern” means a resist pattern formed in this resist film.

Additionally, in the explanation as will be discussed below, a resist material providing the first resist film may be referred to as “a first resist material” for convenience, and a resist material providing the second resist film may be referred to as “a second resist material” for convenience.

As an embodiment of double patterning, it is possible to cite a method of; exposing a first resist film formed on a silicon wafer; then carrying out development by dissolving exposed portions after heat treatment thereby forming a pattern: then forming a second resist film thereon; then exposing the second resist film with a pattern different from that of the first resist film; and then similarly performing a development treatment. With the above operations, it becomes possible to form a pattern finer than conventional patterns. Incidentally, before application of the second resist film, a freezing treatment may be conducted for the purpose of maintaining the pattern formed in the first resist film.

Hereinafter, a pattern-forming method according to double patterning will be further discussed. Incidentally, each of the steps (application, heat treatment, exposure and developing process) can be performed by the same technique as discussed in “Pattern-forming method”.

First of all, a first resist material is prepared and applied to a silicon wafer by spin coating. Then heat treatment is conducted thereby forming a first resist film. Thereafter exposure is conducted by applying a high-energy ray having 300 nm or less wavelengths through a photomask, and then developing process is performed by dissolving exposed portions in a developing solution, thereby forming a first resist pattern is formed in the first resist film.

After that, a second resist material being dissolved in a solvent is applied to the first resist pattern by spin coating and then subjected to heat treatment, thereby forming a second resist film. At this time, the solvent is required not to affect the first resist pattern.

Furthermore, the second resist film is exposed to a high-energy ray having 300 nm or less wavelengths through a photomask by lithography. By using a photomask having a pattern different from that in the first resist film, it becomes possible to achieve an exposure for forming a fine pattern.

Thereafter, heat treatment (i.e. PEB) is conducted as necessary, followed by undergoing a developing process that uses a developing solution, thereby forming a second resist pattern. As the developing solution, there is preferably used a developing solution formed of an alkali aqueous solution such as TMAH and the like, as discussed above.

In the pattern-forming method according to the above-mentioned double patterning, it is required to ensure the combination of the first resist material and the solvent and the combination of the second resist material and the solvent.

The pattern-forming method of the present invention according to double patterning proposes using a resist material containing a polymer having a repeating unit specified in the present invention as the second resist material by preparing the resist material with a specified solvent. Hereinafter, suitable combinations will be discussed.

In the pattern-forming method of the present invention according to double patterning, a solvent used for the second resist material is not particularly limited unless the solvent affects the first resist pattern; however, in the case of using a resist composition for general purposes as the first resist composition, an alcohol-based solvent having 5 to 20 carbon atoms is preferably used.

A resist composition for general purposes as discussed above refers to a resist composition that uses a resin having a repeating unit in which a soluble group such as carboxylic acid group and the like is protected with a unit formed of an alicyclic hydrocarbon such as adamantine, cyclopentane and the like. As the resist composition, a resist composition containing a copolymer formed of, for example, hydroxyadamantyl methacrylate (MA-HAD), ethyladamantyl methacrylate (MA-EAD) or γ-butyrolactone methacrylate (MA-GBL) is preferably used. The above-mentioned copolymers are soluble in polyalcohol derivatives such as propylene glycol monomethyl ether acetate (PGMEA) and propylene glycol monomethyl ether (PGME) or esters such as ethyl lactate (EL) and the like, but insoluble in alcohol-based solvents having 5 to 20 carbon atoms. For example, The above-mentioned copolymers are insoluble in 4-methyl-2-pentanol having 6 carbon atoms.

On the other hand, the polymer of the present invention is excellent in solubility in a wide variety of solvents, and soluble in alcohol-based solvents having 5 to 20 carbon atoms such as 4-methyl-2-pentanol (which may hereinafter be referred to as MIBC) and the like.

The alcohol-based solvents having 5 to 20 carbon atoms can be exemplified by n-pentanol, isopentanol, tert-pentanol, 4-methyl-2-pentanol, 3-methyl-3-pentanol, 2,3-dimethyl-2-pentanol, n-hexanol, n-heptanol, 2-heptanol, n-octanol, n-decanol, s-amyl alcohol, t-amyl alcohol, isoamyl alcohol, 2-ethyl-1-butanol, lauryl alcohol, hexyldecanol, oleyl alcohol and the like. In particular, tert-pentanol, 4-methyl-2-pentanol, 3-methyl-3-pentanol, 2,3-dimethyl-2-pentanol are preferable.

More specifically, a resist composition obtained by preparing a polymer of the present invention with the alcohol-based solvent having 5 to 20 carbon atoms is useful as a resist composition (the above-mentioned second resist composition) to be applied to the second layer in double patterning.

In the above-mentioned double patterning, it is also possible to use one obtained by previously applying the first resist material to a substrate and forming a pattern thereon by lithography. In this case, subsequent processes are required only to include operations to be made after a process for applying the above-mentioned second resist material, in which a pattern is formed by carrying out: a step of applying a resist material onto a substrate previously formed having a resist pattern; a step of exposing the resist material to a high-energy ray having 300 nm or less wavelengths through a photomask after heat treatment; and a step of carrying out development in the use of a developing solution after conducting heat treatment as necessary. As a resist material usable in this case, it is possible to use the resist material of the present invention, and the above-mentioned alcohol-based solvents having 5 to 20 carbon atoms are preferably used as a solvent for preparing this resist material. Incidentally, “a substrate previously formed having a resist pattern” as discussed above is not necessarily a developed one and it is required only that the maintenance of the pattern is achieved by a freezing treatment or the like.

### 12. EUV Lithography

The resist of the present invention exhibits a great sensitivity even if the amount of exposure is small and the PEB temperature is low. Therefore, it can preferably be used as a resist for EUV lithography which is small in output of the light source.

In EUV lithography, a substrate such as a silicon wafer or the like is provided to have a fine pattern by using extreme ultraviolet rays having extremely short wavelengths (EUV having a wavelength of 13.5 nm). It is possible to obtain a fine pattern as compared with a currently used ArF excimer laser.

### EXAMPLES

Hereinafter the present invention will specifically be explained with reference to examples, but the present invention is not limited by the following examples.

Polymers 1 to 6 falling within the range of the present invention were synthesized in Examples 1 to 6, while polymers 7 to 9 not falling within the range of the present invention were synthesized in Comparative Examples 1 to 3.

### Example 1

### Synthesis of Polymer 1

A glass flask was charged with 93.2 g of 2-butanone, 21.2 g of the following 4-oxo-CHMA, 25.4 g of the following ECOMA and 0.3 g of n-dodecyl mercaptan (produced by Tokyo Chemical Industry Co., Ltd.) (the same was used also in the other examples), followed by dissolving them.

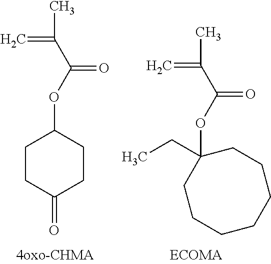 [SMILES: C=C(C)C(=O)OC1CCC(=O)CC1 ; C=C(C)C(=O)OC1(CC)CCCCCCC1]

Then, 1.0 g of 2,2′-azobis(isobutyronitrile) (produced by Wako Pure Chemical Industries, Ltd.) (the same was used also in the other examples and will hereinafter be abbreviated as AIBN) was added to the above-mentioned solution as a polymerization initiator, followed by stirring while performing degasification. Then nitrogen gas was introduced thereinto, followed by conducting a 16 hours of reaction at 75° C. A solution obtained after the reaction terminated was added dropwise to 466 g of n-heptane thereby obtaining a white precipitate. The precipitate was filtered out and dried under a reduced pressure at 60° C. thereby obtaining 37.3 g of a white solid (Polymer 1).

Polymer 1 is a copolymer containing: a repeating unit of the following 4-oxo-CHMA that belongs to a repeating unit represented by the general formula (1); and a repeating unit of the following ECOMA that serves as a repeating unit having an acid-releasable group.

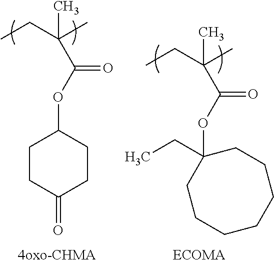

GPC measurement result; Mn=10,800, Mw/Mn=1.8

### Example 2

### Synthesis of Polymer 2

A glass flask was charged with 303.4 g of 2-butanone, 44.5 g of the following 4-oxo-CHMA, 51.5 g of the following MA-EAD, 55.7 g of the following MA35 and 0.3 g of n-dodecyl mercaptan, followed by dissolving them.

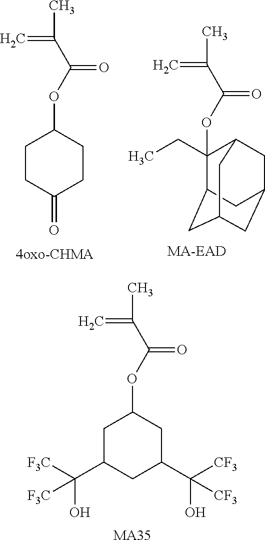

Then, 1.8 g of AIBN was added to the above-mentioned solution as a polymerization initiator, followed by stirring while performing degasification. Then nitrogen gas was introduced thereinto, followed by conducting a 16 hours of reaction at 75° C. A solution obtained after the reaction terminated was added dropwise to 606.8 g of n-heptane thereby obtaining a white precipitate. The precipitate was filtered out and dried under a reduced pressure at 60° C. thereby obtaining 112.26 g of a white solid (Polymer 2).

Polymer 2 is a copolymer containing: a repeating unit of the following 4-oxo-CHMA that belongs to a repeating unit represented by the general formula (1); a repeating unit of the following MA-EAD that serves as a repeating unit having an acid-releasable group; and a repeating unit of the following MA35 that serves as a repeating unit having an adhesive group.

GPC measurement result; Mn=9,500, Mw/Mn=1.9

### Example 3

### Synthesis of Polymer 3

A glass flask was charged with 254.2 g of 2-butanone, 35.0 g of the following 3-oxo-CHMA, 44.6 g of the following MA-ECP, 47.5 g of the following MA3-4OH and 0.15 g of n-dodecyl mercaptan, followed by dissolving them.

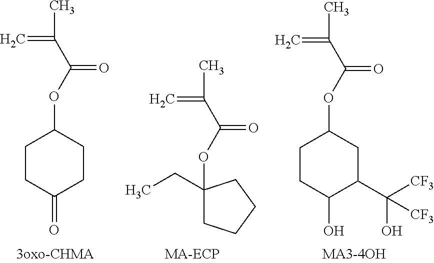

Then, 1.1 g of AIBN was added to the above-mentioned solution as a polymerization initiator, followed by stirring while performing degasification. Then nitrogen gas was introduced thereinto, followed by conducting a 16 hours of reaction at a temperature of 75° C. A solution obtained after the reaction terminated was added dropwise to 508.4 g of n-heptane thereby obtaining a white precipitate. The precipitate was filtered out and dried under a reduced pressure at a temperature of 60° C. thereby obtaining 99.1 g of a white solid as Polymer 3.

Polymer 3 is a copolymer containing: a repeating unit of the following 3-oxo-CHMA that belongs to a repeating unit represented by the general formula (1); a repeating unit of the following MA-ECP that serves as a repeating unit having an acid-releasable group; and a repeating unit of the following MA3-4OH that serves as a repeating unit having an adhesive group.

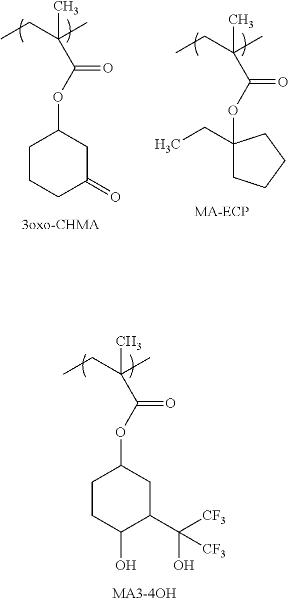

GPC measurement result; Mn=14,500, Mw/Mn=1.6

### Example 4

### Synthesis of Polymer 4

A glass flask was charged with 225.2 g of 2-butanone, 3L8 g of the following 4-oxo-CHMA, 48.8 g of the following MA-ECP, 32.0 g of the following MA-ADOH and 0.35 g of n-dodecyl mercaptan, followed by dissolving them.

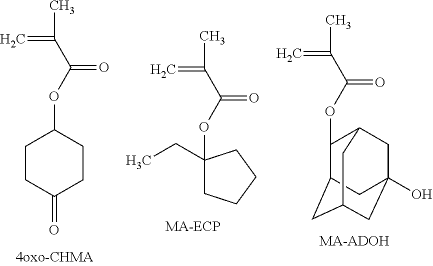

Then, 1.3 g of AIBN was added to the above-mentioned solution as a polymerization initiator, followed by stirring while performing degasification. Then nitrogen gas was introduced thereinto, followed by conducting a 16 hours of reaction at a temperature of 75° C. A solution obtained after the reaction terminated was added dropwise to 450.4 g of n-heptane thereby obtaining a white precipitate. The precipitate was filtered out and dried under a reduced pressure at a temperature of 60° C. thereby obtaining 93.5 g of a white solid as Polymer 4.

Polymer 4 is a copolymer containing: a repeating unit of the following 4-oxo-CHMA that belongs to a repeating unit represented by the general formula (1); a repeating unit of the following MA-ECP that serves as a repeating unit having an acid-releasable group; and a repeating unit of the following MA-ADOH that serves as a repeating unit having an adhesive group.

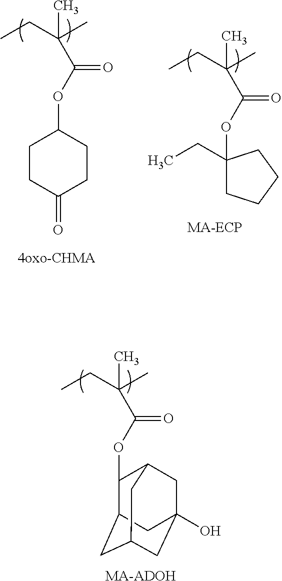

GPC measurement result; Mn=12,200, Mw/Mn=2.1

### Example 5

### Synthesis of Polymer 5

A glass flask was charged with 239.2 g of 2-butanone, 34.0 g of the following 3-oxo-CHMA, 44.6 g of the following MA-ECP, 27.9 g of the following MA-ADOH, 13.1 g of the following TPS-IMA and 0.24 g of n-dodecyl mercaptan, followed by dissolving them.

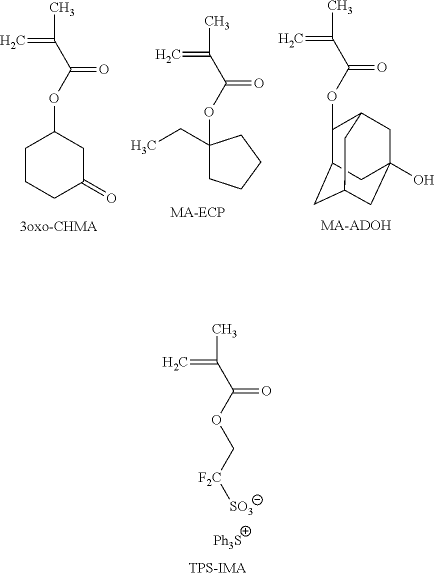

Then, 1.8 g of AIBN was added to the above-mentioned solution as a polymerization initiator, followed by stirring while performing degasification. Then nitrogen gas was introduced thereinto, followed by conducting a 16 hours of reaction at a temperature of 75° C. A solution obtained after the reaction terminated was added dropwise to 478.4 g of n-heptane thereby obtaining a white precipitate. The precipitate was filtered out and dried under a reduced pressure at a temperature of 60° C. thereby obtaining 87.3 g of a white solid as Polymer 5.

Polymer 5 is a copolymer containing: a repeating unit of the following 3-oxo-CHMA that belongs to a repeating unit represented by the general formula (1); a repeating unit of the following MA-ECP that serves as a repeating unit having an acid-releasable group; a repeating unit of the following MA-ADOH that serves as a repeating unit having an adhesive group; and a repeating unit of the following TPS-IMA that serves as a repeating unit having an adhesive group.

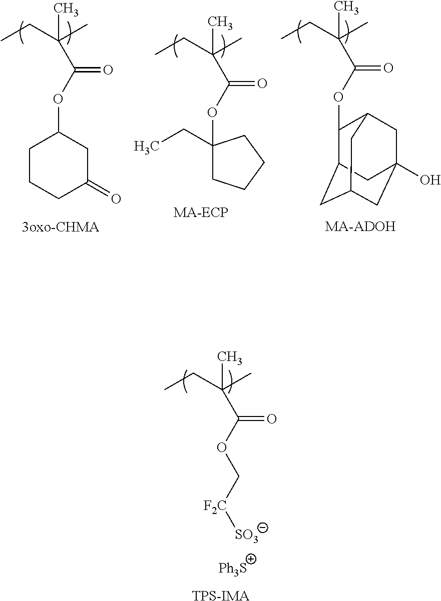

GPC measurement result; Mn=17,800, Mw/Mn=1.9

### Example 6

### Synthesis of Polymer 6

A glass flask was charged with 318 g of 2-butanone, 37.2 g of the following 4-oxo-CHMA, 55.7 g of the following MA-EAD, 53.0 g of the following MA35, 13.1 g of the following TPS-IMA and 0.5 g of n-dodecyl mercaptan, followed by dissolving them.

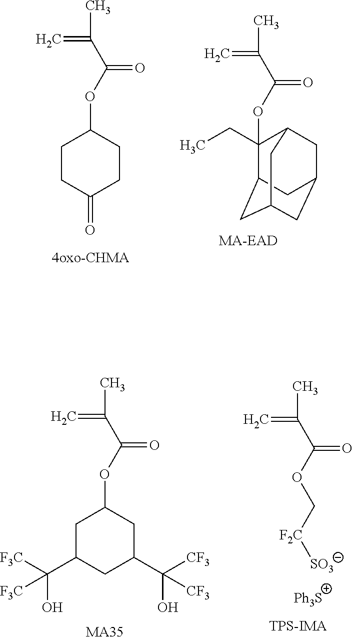

Then, 1.2 g of AIBN was added to the above-mentioned solution as a polymerization initiator, followed by stirring while performing degasification. Then nitrogen gas was introduced thereinto, followed by conducting a 16 hours of reaction at a temperature of 75° C. A solution obtained after the reaction terminated was added dropwise to 636 g of n-heptane thereby obtaining a white precipitate. The precipitate was filtered out and dried under a reduced pressure at a temperature of 60° C. thereby obtaining 128.8 g of a white solid as Polymer 6.

Polymer 6 is a copolymer containing: a repeating unit of the following 4-oxo-CHMA that belongs to a repeating unit represented by the general formula (1); a repeating unit of the following MA-EAD that serves as a repeating unit having an acid-releasable group; a repeating unit of the following MA35 that serves as a repeating unit having an adhesive group; and a repeating unit of the following TPS-IMA that serves as a repeating unit having a salt.

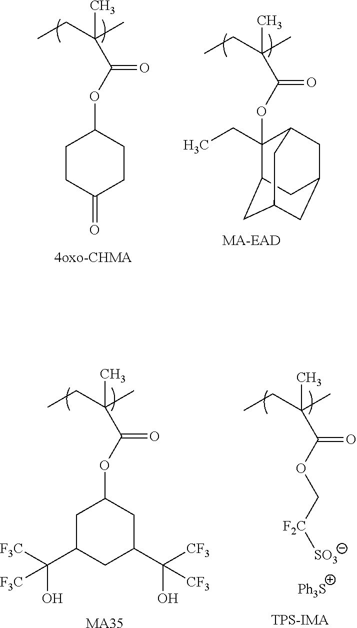

GPC measurement result; Mn=13,800, Mw/Mn=2.0

### Comparative Example 1

### Synthesis of Polymer 7

MA-GBL was used instead of 3-oxo-CHMA of Example 3 thereby synthesizing Polymer 7 not falling within the range of the present invention.

A glass flask was charged with 249.8 g of 2-butanone, 35.0 g of the following MA-GBL, 42.4 g of the following MA-ECP, 47.5 g of the following MA3-4OH and 0.6 g of n-dodecyl mercaptan (produced by Tokyo Chemical Industry Co., Ltd.), followed by dissolving them.

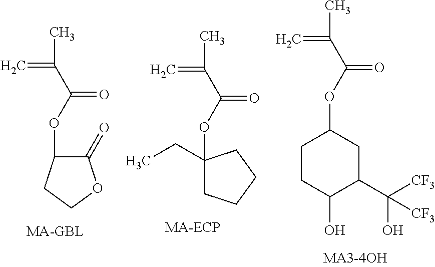

Then, 1.4 g of AIBN was added to the above-mentioned solution as a polymerization initiator, followed by stirring while performing degasification. Then nitrogen gas was introduced thereinto, followed by conducting a 16 hours of reaction at a temperature of 75° C. A solution obtained after the reaction terminated was added dropwise to 499.6 g of n-heptane thereby obtaining a white precipitate. The precipitate was filtered out and dried under a reduced pressure at a temperature of 60° C. thereby obtaining 104.9 g of a white solid as Polymer 7.

Polymer 7 is a copolymer containing: a repeating unit of MA-GBL; a repeating unit of the following MA-ECP that serves as a repeating unit having an acid-releasable group; and a repeating unit of the following MA3-4OH that serves as a repeating unit having an adhesive group. The repeating unit of the following MA-ECP does not belong to the repeating unit represented by the general formula (1).

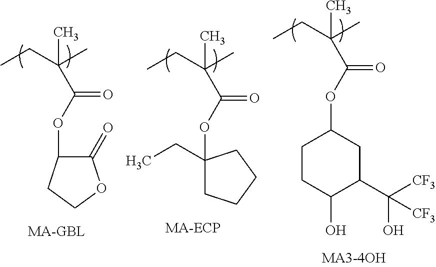

GPC measurement result; Mn=15,900, Mw/Mn=2.4

### Comparative Example 2

### Synthesis of Polymer 8

MA-NL was used instead of 4-oxo-CHMA of Example 4 thereby synthesizing Polymer 8 not falling within the range of the present invention.

A glass flask was charged with 238 g of 2-butanone, 35.3 g of the following MA-NL, 47.7 g of the following MA-ECP, 36.0 g of the following MA-ADOH and 0.6 g of n-dodecyl mercaptan, followed by dissolving them.

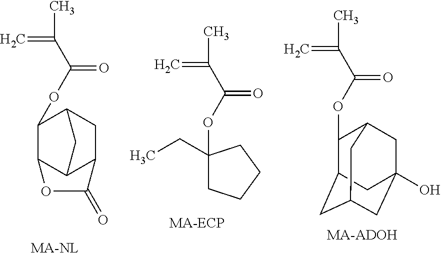

Then, 1.6 g of AIBN was added to the above-mentioned solution as a polymerization initiator, followed by stirring while performing degasification. Then nitrogen gas was introduced thereinto, followed by conducting a 16 hours of reaction at a temperature of 75° C. A solution obtained after the reaction terminated was added dropwise to 476 g of n-heptane thereby obtaining a white precipitate. The precipitate was filtered out and dried under a reduced pressure at a temperature of 60° C. thereby obtaining 88.1 g of a white solid (Polymer 8).

Polymer 8 is a copolymer containing: a repeating unit of MA-NL; a repeating unit of the following MA-ECP that serves as a repeating unit having an acid-releasable group; and a repeating unit of the following MA-ADOH that serves as a repeating unit having an adhesive group. The repeating unit of the following MA-NL does not belong to the repeating unit represented by the general formula (1).

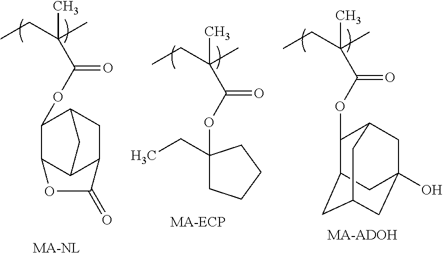

GPC measurement result; Mn=14,700, Mw/Mn=1.5

### Comparative Example 3

### Synthesis of Polymer 9

MA-GBL was used instead of 3-oxo-CHMA of Example 5 thereby synthesizing Polymer 9 not falling within the range of the present invention.

A glass flask was charged with 235.4 g of 2-butanone, 36.0 g of the following MA-GBL, 42.4 g of the following MA-ECP, 25.3 g of the following MA-ADOH and 0.4 g of n-dodecyl mercaptan, followed by dissolving them.

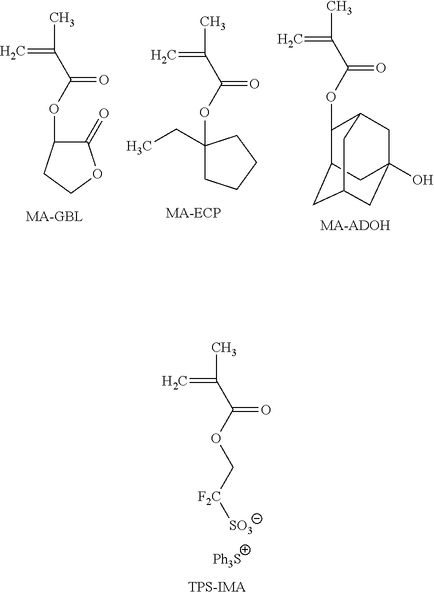

Then, 1.3 g of AIBN was added to the above-mentioned solution as a polymerization initiator, followed by stirring while performing degasification. Then nitrogen gas was introduced thereinto, followed by conducting a 16 hours of reaction at a temperature of 75° C. A solution obtained after the reaction terminated was added dropwise to 470.8 g of n-heptane thereby obtaining a white precipitate. The precipitate was filtered out and dried under a reduced pressure at a temperature of 60° C. thereby obtaining 74.2 g of a white solid (Polymer 9).

Polymer 9 is a copolymer containing: a repeating unit of MA-GBL; a repeating unit of the following MA-ECP that serves as a repeating unit having an acid-releasable group; a repeating unit of the following MA-ADOH that serves as a repeating unit having an adhesive group; and a repeating unit of the following TPS-IMA that serves as a repeating unit having a salt. The repeating unit of the following MA-GBL does not belong to the repeating unit represented by the general formula (1).

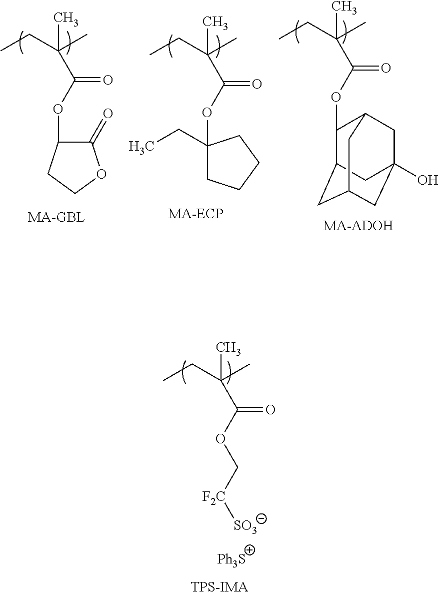

GPC measurement result; Mn=18,400, Mw/Mn=2.3

[Polymerization Result]

The molecular weight and the composition of the polymers obtained by Examples 1 to 6 and Comparative Examples 1 to 3 were measured. The molecular weight (the number average molecular weight “Mn”) and the molecular weight distribution (the ratio between “Mn” and the weight average molecular weight “Mw”, represented by “Mw/Mn”) of the polymer were measured by using a high speed GPC apparatus (available from TOSOH CORPORATION under the trade name of HLC-8320GPC) in which one ALPHA-M column and one ALPHA-2500 column (produced by TOSOH CORPORATION) were connected in series and tetrahydrofuran was used as a developing solvent. As a detector, a differential refractive index detector was adopted. Additionally, the composition of the polymer was ascertained by ¹H-NMR and ¹⁹F-NMR.

Results of having measured the composition (mol %), the yield (%) and the molecular weight of each polymer are shown in Table 1.

TABLE 1

| | | | | | Molecular | | |
|---|---|---|---|---|---|---|---|
| | | | | | Weight | | Yield |
| | Composition (mol %) | | | | Mw | Mw/Mn | (%) |
| Example 1 | 4oxo-CHMA | ECOMA | — | — | 10,800 | 1.8 | 80 |
| (Polymer 1) | 52 | 48 | | | | | |
| Example 2 | 4oxo-CHMA | MA-EAD | MA-35 | — | 9,500 | 1.9 | 74 |
| (Polymer 2) | 42 | 37 | 21 | | | | |
| Example 3 | 3oxo-CHMA | MA-ECP | MA3-4OH | — | 14,500 | 1.6 | 78 |
| (Polymer 3) | 33 | 42 | 25 | | | | |
| Example 4 | 4oxo-CHMA | MA-ECP | MA-ADOH | — | 12,200 | 2.1 | 83 |
| (Polymer 4) | 30 | 46 | 24 | | | | |
| Example 5 | 3oxo-CHMA | MA-EAD | MA-ADOH | TPS-IMA | 17,800 | 1.9 | 73 |
| (Polymer 5) | 35 | 40 | 21 | 5 | | | |
| Example 6 | 4oxo-CHMA | MA-ECP | MA35 | TPS-IMA | 13,800 | 2.0 | 81 |
| (Polymer 6) | 35 | 40 | 35 | 5 | | | |
| Comparative | MA-GBL | MA-ECP | MA3-4OH | — | 15,900 | 2.4 | 84 |
| Example 1 | 35 | 40 | 25 | | | | |
| (Polymer 7) | | | | | | | |
| Comparative | MA-NL | MA-ECP | MA-ADOH | — | 14,700 | 1.5 | 74 |
| Example 2 | 28 | 45 | 27 | | | | |
| (Polymer 8) | | | | | | | |
| Comparative | MA-GBL | MA-ECP | MA-ADOH | TPS-IMA | 18,400 | 2.3 | 63 |
| Example 3 | 36 | 40 | 19 | 5 | | | |
| (Polymer 9) | | | | | | | |

[Preparation of Resist]

Polymers 1 to 9 having been synthesized by Examples 1 to 6 and Comparative Examples 1 to 3 were subjected to the addition of a photoacid generator, a basic compound and a solvent, thereby obtaining resist solutions (Resist 1 to 9, respectively). The mixing ratios are shown in Table 2.

The thus prepared resist solution was filtered through a membrane filter having a pore diameter of 0.2 μm and then applied onto a silicon wafer with a spinner at a rotation speed of 1,500 rpm, followed by drying on a hot plate of 100° C. for 90 seconds, the silicon wafer being obtained by being coated with an antireflective film of 78 nm thickness (available from Nissan Chemical Industries, Ltd. under the trade name of ARC29A) and then calcined at a temperature of 200° C. for 60 seconds to be dried.

[Measurement of Contact Angle]

A resin film thus formed on the silicon wafer was subjected to measurement in terms of the contact angle of water, by using a contact angle meter (produced by Kyowa Interface Science Co., Ltd.). Results are shown in Table 2.

Concerning the resin films formed of Resists 1 to 6 containing Polymers 1 to 6 that belong to the present invention and the resin films formed of Resists 7 to 9 containing Polymers 7 to 9 that does not belong the present invention, it was found from Table 2 that the contact angle was large in either case. The resin films formed of Resists 1 to 6 containing Polymers 1 to 6 that belong to the present invention had a large contact angle as compared with the resin films formed of Resists 7 to 9 containing Polymers 7 to 9 that does not belong the present invention.

Thus the resin films formed of Resists 1 to 6 (Examples 1 to 6) had great water repellency as compared to the resin films formed of Resists 7 to 9 (Comparative Examples 1 to 3), and therefore expected to prevent the resist from immersion in water in immersion lithography using an immersion exposure apparatus thereby suppressing the occurrence of watermark defect (a defect caused by waterdrop remaining after rinsing at the time of development).

TABLE 2

| | Composition Ratio (parts by mass) | | | | |
|---|---|---|---|---|---|
| | | Photoacid | Basic | | Contact |
| | Polymer | Generator | Compound | Solvent | Angle |
| Example 1 | Polymer 1 | PAG-1 | Base-1 | PEGMIA | 72 |
| (Resist 1) | (100) | (5) | (5) | (900) | |
| Example 2 | Polymer 2 | PAG-1 | Base-1 | PEGMIA | 71 |
| (Resist 2) | (100) | (5) | (5) | (900) | |
| Example 3 | Polymer 3 | PAG-1 | Base-1 | PEGMIA | 74 |
| (Resist 3) | (100) | (5) | (5) | (900) | |
| Example 4 | Polymer 4 | PAG-2 | Base-2 | PEGMIA | 73 |
| (Resist 4) | (100) | (5) | (5) | (900) | |
| Example 5 | Polymer 5 | — | Base-2 | PEGMIA | 77 |
| (Resist 5) | (100) | | (5) | (900) | |
| Example 6 | Polymer 6 | — | Base-2 | PEGMIA | 78 |
| (Resist 6) | (100) | | (5) | (900) | |
| Comparative | Polymer 7 | PAG-1 | Base-1 | PEGMIA | 65 |
| Example 1 | (100) | (5) | (5) | (900) | |
| (Resist 7) | | | | | |
| Comparative | Polymer 8 | PAG-2 | Base-2 | PEGMIA | 64 |
| Example 2 | (100) | (5) | (5) | (900) | |
| (Resist 8) | | | | | |
| Comparative | Polymer 9 | — | Base-2 | PEGMIA | 67 |
| Example 3 | (100) | | (5) | (900) | |
| (Resist 9) | | | | | |

PAG-1: Triphenylsulfonium nonafluorobutanesulfonate
PAG-2: Triphenylsulfonium trifluorobutanesulfonate
Base-1: Isopropanolamine
Base-2: Triethanolamine
PEGMIA: Propylene glycol monomethyl ether acetate

[Test of Solubility in Developing Solution]

A silicon wafer to which a resist was so applied as to form a resin film as discussed above was immersed in an alkali developing solution (2.38 mass % tetramethylammonium hydroxide aqueous solution) and then subjected to a test in terms of solubility. Dissolution of the resin was examined by measuring a film that remained after immersion, with the use of a film thickness meter applying interference of light. Results of the test were shown in Table 3.

As shown by Table 3, it was found that Resists 1 to 9 were insoluble in the alkali developing solution in an unexposed state while becoming soluble after exposure. It became evident from the above that all of the examined resists have a dissolution contrast as a photosensitive resin.

[Examination of Exposure Resolution]

A silicon wafer to which a resist was so applied as to form a resin film as discussed above was subjected to a prebake at 100° C. for 60 seconds, followed by exposing it to ultraviolet rays having a wavelength of 193 nm by ArF excimer laser through a photomask. While rotating the wafer obtained after exposure, pure water was added thereto dropwise for 2 minutes. Thereafter a PEB was performed at 120° C. for 60 seconds, followed by conducting development with an alkali developing solution.

The obtained pattern was observed by a scanning electron microscope (SEM), followed by carrying out an evaluation of the resolution performance.

In the cases of using Resists 1 to 6 (Examples 1 to 6), a pattern having a rectangular cross section and not having roughness and defects was formed, so that a highly excellent resolution performance was exhibited. On the contrary, in the cases of using Resists 7 to 9 (Comparative Examples 1 to 3), there was observed a pattern having: an outstretched-head shape (a shape of the cross section of a resist pattern, in which the line width of an upper portion is larger than that of a lower portion) considered to be derived from poor solubility in a developing solution; and a lot of defects caused by residue.

[Test of Solvent Solubility in 4-methyl-2-pentanol (MIBC)]

A silicon wafer to which a resist material prepared at the above-mentioned mixing ratio was so applied as to form a resin film was immersed in MIBC and then subjected to a test in terms of solubility. Results of the solubility test were shown in Table 3.

In the case of using Resists 1 to 6 (Examples 1 to 6), the resist have a lot of carbonyl groups (serving as polar groups) therein. Hence these resists dissolved rapidly in MIBC (i.e., an alcohol-based solvent having a slight polarity) and independently exhibited a great solubility. On the other hand, when Resists 7 to 9 were used (Comparative Examples 1 to 3), it was observed that the resists were insoluble or had no solvent solubility in MIBC.

From these experimental results, it was found that Resists 1 to 6 containing Polymers 1 to 6 of the present invention as a resist material for forming a second resist film were so soluble in MIBC as to allow preparing a resist solution, in the case of using a general purpose resist composition for a first resist film according to a pattern-forming method where a second resist film is applied to a first resist film that have been formed with a pattern and then an exposure treatment is performed, i.e., double patterning method.

More specifically, the solvent (MIBC) used for the second resist material does not affect the resist pattern formed on the first resist film, so that it becomes possible to form the second resist film without affecting the first resist pattern.

TABLE 3

| | Solubility in Alkali | | | |
|---|---|---|---|---|
| | Developing Solution | | Solvent | |
| | Before | After | Solubility | Resolution |
| | Exposure | Exposure | (MIBC) | Performance |
| Example 1 | Insoluble | Soluble | Soluble | Rectangular Pattern |
| (Resist 1) | | | | |
| Example 2 | Insoluble | Soluble | Soluble | Rectangular Pattern |
| (Resist 2) | | | | |
| Example 3 | Insoluble | Soluble | Soluble | Rectangular Pattern |
| (Resist 3) | | | | |
| Example 4 | Insoluble | Soluble | Soluble | Rectangular Pattern |
| (Resist 4) | | | | |
| Example 5 | Insoluble | Soluble | Soluble | Rectangular Pattern |
| (Resist 5) | | | | |
| Example 6 | Insoluble | Soluble | Soluble | Rectangular Pattern |
| (Resist 6) | | | | |
| Comparative | Insoluble | Soluble | Insoluble | Pattern having |
| Example 1 | | | | outstretched-head |
| (Resist 7) | | | | shape and defects |
| | | | | caused by residue |
| Comparative | Insoluble | Soluble | Insoluble | Pattern having |
| Example 2 | | | | outstretched-head |
| (Resist 8) | | | | shape and defects |
| | | | | caused by residue |
| Comparative | Insoluble | Soluble | Insoluble | Pattern having |
| Example 3 | | | | outstretched-head |
| (Resist 9) | | | | shape and defects |
| | | | | caused by residue |

MIBC: 4-methyl-2-pentanol

### INDUSTRIAL APPLICABILITY

The resist material of the present invention does not particularly limit the light source and the wavelength to be used for exposure; however, the resist material of the present invention can be preferably used for lithographic micropatterning employing KrF excimer laser, ArF excimer laser, F₂ excimer laser, EUV, EB or X-rays. In particular, the resist material is preferably adopted for lithography using KrF excimer laser, ArF excimer laser or EUV.

The resist material of the present invention is particularly useful as a resist material for use in immersion lithography employing ArF excimer laser, a resist material for use in double patterning or a resist material for use in EUV.

1. A polymer comprising:
a repeating unit represented by the following general formula (1); and
a repeating unit having an acid-releasable group. 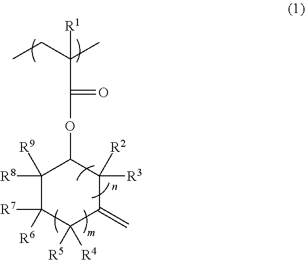
R¹ mutually independently represents a hydrogen atom, a halogen atom, a methyl group, or a trifluoromethyl group;
R² to R⁹ mutually independently represent a hydrogen atom, a C₁-C₂₀ linear or C₃-C₂₀ branched or cyclic hydrocarbon group, wherein some of the carbon atoms constituting the hydrocarbon groups may be replaced with oxygen atom(s), two hydrogen atoms binding to the same carbon may be replaced with an oxygen atom to form ═O, H of a C—H bond of the hydrocarbon may be replaced with OH to form C—OH, and some or all of the hydrogen atoms constituting R² to R⁹ may be replaced with fluorine atom(s); wherein some or all of R² to R⁹ may be combined to form a cyclic compound, and wherein “n” and “m” mutually independently represent an integer of 0 to 5.

2. A polymer as claimed in claim 1, further comprising a repeating unit having 1,1,1,3,3,3-hexafluoro-2-hydroxyisopropyl group or a repeating unit having an adhesive group.

3. A polymer as claimed in claim 1, further comprising a repeating unit having a salt represented by the following formula (2) or the following general formula (3). 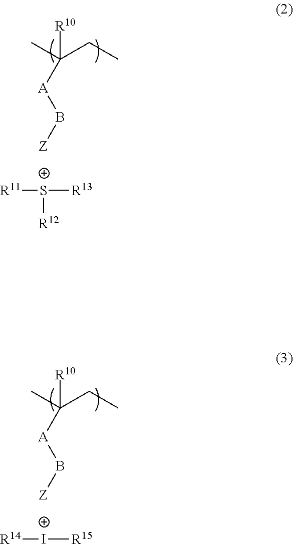
(In the formulas (2) and (3), R¹⁰ mutually independently represents a hydrogen atom, a halogen atom, a methyl group, or a trifluoromethyl group. “A” mutually independently represents a single bond, a methylene group, a phenylene group, —O—, —(C═O)—O— or —(C═O)—NR¹⁶—, wherein R¹⁶ mutually independently represents a hydrogen atom, a C₁-C₂₀ linear, branched or cyclic hydrocarbon group, some or all of the hydrogen atoms may be replaced with fluorine atom(s), hydroxyl group(s) or alkoxyl group(s), and the hydrocarbon group may have at least one kind selected from —O—, —(C═O)—O—, —(C═O)—NH—, —(C═O)—, —O—(C═O)—NH— and —NH—(C═O)—NH—. “B” mutually independently represents a single bond, a C₁-C₂₀ linear or C₃-C₂₀ branched or cyclic alkylene or phenylene group, wherein some or all of the hydrogen atoms may be replaced with fluorine atom(s), hydroxyl group(s) or alkoxyl group(s), and the hydrocarbon group may have at least one kind selected from —O—, —(C═O)—O—, —(C═O)—NH—, —(C═O)—, —O—(C═O)—NH— and —NH—(C═O)—NH—. “Z” mutually independently represents SO₃⁻, CO₂⁻, (CF₃SO₂)₂C⁻, or CF₃SO₂N⁻. R¹¹ to R¹³ mutually independently represent a C₁-C₃₀ linear or C₃-C₃₀ branched alkyl group that may have a substituent, a C₃-C₃₀ cyclic monovalent hydrocarbon group that may have a substituent, a C₆-C₃₀ aryl group that may have a substituent, or a monovalent heterocyclic organic group that may have a substituent and has the number of atoms of 4 to 30, wherein any two or more of R¹¹ to R¹³ may be bonded to each other through a sulfur atom to form a cyclic structure. R¹⁴ and R¹⁵ mutually independently represent a C₁-C₃₀ linear or branched alkyl group that may have a substituent, a C₃-C₃₀ cyclic monovalent hydrocarbon group that may have a substituent, a C₆-C₃₀ aryl group that may have a substituent, or a monovalent heterocyclic organic group that may have a substituent and has the number of atoms of 4 to 30. Alternatively, R¹⁴ and R¹⁵ may be bonded to each other through an iodine atom to form a cyclic structure.)

4. A resist material comprising a polymer as claimed in claim 1.

5. A resist material as claimed in claim 4, further comprising at least one kind of an acid generator, a basic compound and an organic solvent.

6. A resist material as claimed in claim 5, wherein a C₅-C₂₀ alcohol-based solvent is used as the organic solvent.

7. A pattern-forming method comprising:
a first step of applying a resist material as claimed in claim 4 to a substrate;
a second step of subjecting the substrate to heat treatment to form a resist film and then exposing the resist film to an ultraviolet light or extreme ultraviolet light having a wavelength of 300 nm or less through a photomask by using an exposure apparatus; and
a third step of carrying out development by dissolving an exposed portion of the resist film in a developing solution thereby forming a pattern in the substrate.

8. A pattern-forming method as claimed in claim 7, the method adopting immersion lithography where water is inserted between a wafer and a projection lens and an ultraviolet light is radiated from an ArF excimer laser of a wavelength of 193 nm in use of an exposure apparatus.

9. A pattern-forming method according to double patterning where a first resist pattern is formed on a substrate and then a second resist pattern is formed on the first resist pattern, wherein a resist material as claimed in claim 4 is used.

10. A pattern-forming method according to EUV lithography that uses an ultraviolet light having a wavelength of 13.5 nm, wherein a resist material as claimed in claim 4 is used.
